(19) United States
(12) Patent Application Publication
(10) Pub. No.: US 2025/0131168 A1
(43) Pub. Date: Apr. 24, 2025

(54) AUTOMATIC WELL TEST VALIDATION

(71) Applicant: Schlumberger Technology Corporation, Sugar Land, TX (US)

(72) Inventors: Chao Gao, Menlo Park, CA (US); Nghia Tri Vo, Kuala Lumpur (MY)

(21) Appl. No.: 18/924,668

(22) Filed: Oct. 23, 2024

Related U.S. Application Data
(60) Provisional application No. 63/592,699, filed on Oct. 24, 2023.
(60) Provisional application No. 63/592,688, filed on Oct. 24, 2023.

(51) Int. Cl. G06F 30/27; G06F 30/28

(52) U.S. Cl. CPC G06F 30/27; G06F 30/28

(57) ABSTRACT

A method for validating a well test includes receiving historical well test data. The historical well test data includes one or more accepted flags and one or more rejected flags. The method also includes training a machine-learning (ML) model based upon the historical well test data to produce a trained ML model. The method also includes receiving new well test data. The new well test data does not include the one or more accepted flags and the one or more rejected flags. The method also includes determining whether the new well test data meets or exceeds a predetermined validation threshold using the trained ML model.

### CROSS-REFERENCE TO RELATED APPLICATIONS

This application claims priority to U.S. Provisional Patent Application No. 63/592,688 and U.S. Provisional Patent Application No. 63/592,699, both of which were filed on Oct. 24, 2023, and both of which are incorporated by reference.

### BACKGROUND

In the specific context of the oil and gas sector, the evaluation of oil producers' performance and productivity through production well tests hold significance. These tests are conducted using multiphase meters either at individual wells or through shared separators. Especially in offshore platforms, economic considerations favor the latter strategy. Here, test separators are shared among interconnected wells, and each well undergoes periodic testing. Separator well tests involve the systematic gathering of flow rate, pressure, and temperature data at regular intervals over a defined period, often spanning from 12 to 24 hours per well monthly. The intention behind these tests is to gain insights into reservoir behavior, product lifting mechanisms, and the effectiveness of production strategies.

However, the intricacies arise due to the sheer volume and complexity of the data involved. The manual validation process becomes cumbersome, susceptible to human errors, which can lead to inaccuracies. Factors such as fluid properties, wellbore dynamics, and measurement uncertainties contribute to variations in the data, further complicating the process. As a result, expertise and careful analysis are used to discern valid data from noise.

To surmount these challenges, endeavors have been made to automate the validation of well tests. Software tools and algorithms have been developed to identify patterns, outliers, and inconsistencies within the data, effectively reducing manual intervention. While these tools enhance the validation process, they sometimes struggle with capturing uncertainties tied to production activities. Additionally, the computational demands of these tools are substantial due to the intricate nature of the problems and variables at play.

To address these challenges, previous approaches have been employed to assist with well test validation. Software tools and automated algorithms have been utilized to streamline data analysis and decrease manual efforts. These tools excel in identifying trends, spotting outliers, and revealing data inconsistencies, leading to a more efficient validation process. Although these computational models can be employed for validating production tests, they frequently struggle to account for uncertainties and errors associated with production activities due to their complexity and numerous variables. A ML development framework has also been conceived and introduced, emphasizing its extensibility, efficiency, and scalability for application within the oil and gas industry.

### SUMMARY

A method for validating a well test is disclosed. The method includes receiving historical well test data. The historical well test data includes one or more accepted flags and one or more rejected flags. The method also includes training a machine-learning (ML) model based upon the historical well test data to produce a trained ML model. The method also includes receiving new well test data. The new well test data does not include the one or more accepted flags and the one or more rejected flags. The method also includes determining whether the new well test data meets or exceeds a predetermined validation threshold using the trained ML model.

A computing system is also disclosed. The computing system includes one or more processors and a memory system. The memory system includes one or more non-transitory computer-readable media storing instructions that, when executed by at least one of the one or more processors, cause the computing system to perform operations. The operations include receiving historical well test data. The historical well test data includes one or more accepted flags and one or more rejected flags. The one or more accepted flags correspond to a first portion of the historical well test data that has been accepted. The one or more rejected flags correspond to a second portion of the historical well test data that has been rejected. The operations also include training a machine-learning (ML) model based upon the historical well test data to produce a trained ML model. The operations also include receiving new well test data. The new well test data does not include the one or more accepted flags and the one or more rejected flags. The operations also include determining whether the new well test data meets or exceeds a predetermined validation threshold using the trained ML model. The predetermined validation threshold includes a minimum sustained flow rate of hydrocarbons for more than a predetermined amount of time.

A non-transitory computer-readable medium is also disclosed. The medium stores instructions that, when executed by one or more processors of a computing system, cause the computing system to perform operations. The operations include receiving historical well test data. The historical well test data includes one or more accepted flags and one or more rejected flags. The one or more accepted flags correspond to a first portion of the historical well test data that has been accepted. The one or more rejected flags correspond to a second portion of the historical well test data that has been rejected. The operations also include training a machine-learning (ML) model based upon the historical well test data to produce a trained ML model. The operations also include receiving new well test data. The new well test data does not include the one or more accepted flags and the one or more rejected flags. The operations also include determining whether the new well test data meets or exceeds a predetermined validation threshold using the trained ML model. The predetermined validation threshold includes a minimum sustained flow rate of hydrocarbons for more than a predetermined amount of time.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIG. 1 illustrates an example of a system that includes various management components to manage various aspects of a geologic environment, according to an embodiment.

FIG. 2 illustrates an operational framework and data flow, according to an embodiment.

FIG. 3 illustrates a comprehensive table that encompasses the well test parameters used for validation, according to an embodiment.

FIG. 4 illustrates a Shapley interpretation to explain features that contribute to prediction of an ML model, according to an embodiment.

FIG. 5A illustrates a well test validation summary including MTD active vs. well test status, FIG. 5B illustrates a well test validation summary including a predicted confidence score (to be validated), and FIG. 5C illustrates a well test validation summary including a late validation notification, according to an embodiment.

FIG. 6 illustrates a well test validation table, according to an embodiment.

FIG. 7 illustrates well test comments, operational remarks, and well test trend plots with notifications, according to an embodiment.

FIGS. 8A-8C illustrate an operational solution framework, according to an embodiment.

FIG. 9 illustrates a flowchart of a method for validating a well test, according to an embodiment.

FIGS. 10A-10C illustrate a flowchart showing well test validation using machine learning and natural language processing, according to an embodiment.

FIG. 11 illustrates a well test comment value extraction, according to an embodiment.

FIG. 12 illustrates a well test comment keyword action extraction, according to an embodiment.

FIG. 13A illustrates ACF auto-correlation for a valid well test property (e.g., Bsw vs number of lag), and FIG. 13B illustrates PACF auto-correlation for the valid well test property (e.g., Bsw vs number of lag), according to an embodiment.

FIG. 14A illustrates ACF auto-correlation for a valid well test property (e.g., oil production rate vs number of lag), and FIG. 14B illustrates PACF auto-correlation for the valid well test property (e.g., oil production rate vs number of lag), according to an embodiment.

FIG. 15A illustrates ACF auto-correlation for a valid well test property (e.g., water production rate vs number of lag), and FIG. 15B illustrates PACF auto-correlation for the valid well test property (e.g., water production rate vs number of lag), according to an embodiment.

FIG. 16 illustrates correlation matrix, according to an embodiment.

FIG. 17 illustrates a well test history including a plurality of parameters showing valid well tests and invalid well tests, according to an embodiment.

FIGS. 18A and 18B illustrate results from a random forest algorithm, a logistic regression algorithm, an XGBoost algorithm, a decision tree algorithm, and an SVM algorithm, according to an embodiment.

FIG. 19 illustrates a graph showing top feature importance using a random forest algorithm, according to an embodiment.

FIG. 20 illustrates a flowchart of a method for validating a well test, according to an embodiment.

FIG. 21 illustrates a schematic view of a computing system for performing at least a portion of the method(s) herein, according to an embodiment.

### DETAILED DESCRIPTION

Reference will now be made in detail to embodiments, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits, and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques, and workflows that are in accordance with some embodiments. Some operations in the processing procedures, methods, techniques, and workflows disclosed herein may be combined and/or the order of some operations may be changed.

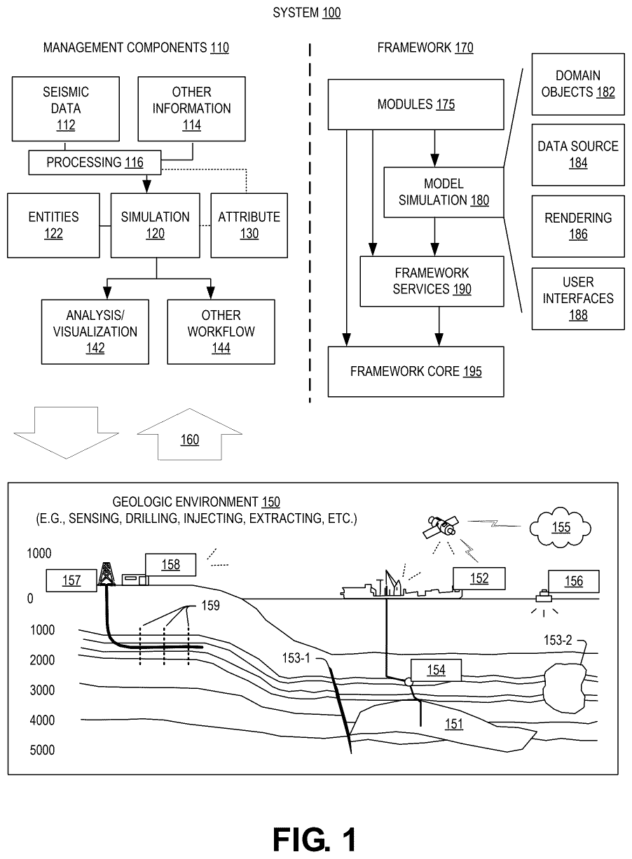

FIG. 1 illustrates an example of a system 100 that includes various management components 110 to manage various aspects of a geologic environment 150 (e.g., an environment that includes a sedimentary basin, a reservoir 151, one or more faults 153-1, one or more geobodies 153-2, etc.). For example, the management components 110 may allow for direct or indirect management of sensing, drilling, injecting, extracting, etc., with respect to the geologic environment 150. In turn, further information about the geologic environment 150 may become available as feedback 160 (e.g., optionally as input to one or more of the management components 110).

In the example of FIG. 1, the management components 110 include a seismic data component 112, an additional information component 114 (e.g., well/logging data), a processing component 116, a simulation component 120, an attribute component 130, an analysis/visualization component 142 and a workflow component 144. In operation, seismic data and other information provided per the components 112 and 114 may be input to the simulation component 120.

In an example embodiment, the simulation component 120 may rely on entities 122. Entities 122 may include earth entities or geological objects such as wells, surfaces, bodies, reservoirs, etc. In the system 100, the entities 122 can include virtual representations of actual physical entities that are reconstructed for purposes of simulation. The entities 122 may include entities based on data acquired via sensing, observation, etc. (e.g., the seismic data 112 and other information 114). An entity may be characterized by one or more properties (e.g., a geometrical pillar grid entity of an earth model may be characterized by a porosity property). Such properties may represent one or more measurements (e.g., acquired data), calculations, etc.

In an example embodiment, the simulation component 120 may operate in conjunction with a software framework such as an object-based framework. In such a framework, entities may include entities based on pre-defined classes to facilitate modeling and simulation. A commercially available example of an object-based framework is the MICROSOFT®.NET® framework (Redmond, Washington), which provides a set of extensible object classes. In the .NET® framework, an object class encapsulates a module of reusable code and associated data structures. Object classes can be used to instantiate object instances for use in by a program, script, etc. For example, borehole classes may define objects for representing boreholes based on well data.

In the example of FIG. 1, the simulation component 120 may process information to conform to one or more attributes specified by the attribute component 130, which may include a library of attributes. Such processing may occur prior to input to the simulation component 120 (e.g., consider the processing component 116). As an example, the simulation component 120 may perform operations on input information based on one or more attributes specified by the attribute component 130. In an example embodiment, the simulation component 120 may construct one or more models of the geologic environment 150, which may be relied on to simulate behavior of the geologic environment 150 (e.g., responsive to one or more acts, whether natural or artificial). In the example of FIG. 1, the analysis/visualization component 142 may allow for interaction with a model or model-based results (e.g., simulation results, etc.). As an example, output from the simulation component 120 may be input to one or more other workflows, as indicated by a workflow component 144.

As an example, the simulation component 120 may include one or more features of a simulator such as the ECLIPSE™ reservoir simulator (Schlumberger Limited, Houston Texas), the INTERSECT™ reservoir simulator (Schlumberger Limited, Houston Texas), etc. As an example, a simulation component, a simulator, etc. may include features to implement one or more meshless techniques (e.g., to solve one or more equations, etc.). As an example, a reservoir or reservoirs may be simulated with respect to one or more enhanced recovery techniques (e.g., consider a thermal process such as SAGD, etc.).

In an example embodiment, the management components 110 may include features of a commercially available framework such as the PETREL® seismic to simulation software framework (Schlumberger Limited, Houston, Texas). The PETREL® framework provides components that allow for optimization of exploration and development operations. The PETREL® framework includes seismic to simulation software components that can output information for use in increasing reservoir performance, for example, by improving asset team productivity. Through use of such a framework, various professionals (e.g., geophysicists, geologists, and reservoir engineers) can develop collaborative workflows and integrate operations to streamline processes. Such a framework may be considered an application and may be considered a data-driven application (e.g., where data is input for purposes of modeling, simulating, etc.).

In an example embodiment, various aspects of the management components 110 may include add-ons or plug-ins that operate according to specifications of a framework environment. For example, a commercially available framework environment marketed as the OCEAN® framework environment (Schlumberger Limited, Houston, Texas) allows for integration of add-ons (or plug-ins) into a PETREL® framework workflow. The OCEAN® framework environment leverages.NET® tools (Microsoft Corporation, Redmond, Washington) and offers stable, user-friendly interfaces for efficient development. In an example embodiment, various components may be implemented as add-ons (or plug-ins) that conform to and operate according to specifications of a framework environment (e.g., according to application programming interface (API) specifications, etc.).

FIG. 1 also shows an example of a framework 170 that includes a model simulation layer 180 along with a framework services layer 190, a framework core layer 195 and a modules layer 175. The framework 170 may include the commercially available OCEAN® framework where the model simulation layer 180 is the commercially available PETREL® model-centric software package that hosts OCEAN® framework applications. In an example embodiment, the PETREL® software may be considered a data-driven application. The PETREL® software can include a framework for model building and visualization.

As an example, a framework may include features for implementing one or more mesh generation techniques. For example, a framework may include an input component for receipt of information from interpretation of seismic data, one or more attributes based at least in part on seismic data, log data, image data, etc. Such a framework may include a mesh generation component that processes input information, optionally in conjunction with other information, to generate a mesh.

In the example of FIG. 1, the model simulation layer 180 may provide domain objects 182, act as a data source 184, provide for rendering 186 and provide for various user interfaces 188. Rendering 186 may provide a graphical environment in which applications can display their data while the user interfaces 188 may provide a common look and feel for application user interface components.

As an example, the domain objects 182 can include entity objects, property objects and optionally other objects. Entity objects may be used to geometrically represent wells, surfaces, bodies, reservoirs, etc., while property objects may be used to provide property values as well as data versions and display parameters. For example, an entity object may represent a well where a property object provides log information as well as version information and display information (e.g., to display the well as part of a model).

In the example of FIG. 1, data may be stored in one or more data sources (or data stores, generally physical data storage devices), which may be at the same or different physical sites and accessible via one or more networks. The model simulation layer 180 may be configured to model projects. As such, a particular project may be stored where stored project information may include inputs, models, results and cases. Thus, upon completion of a modeling session, a user may store a project. At a later time, the project can be accessed and restored using the model simulation layer 180, which can recreate instances of the relevant domain objects.

In the example of FIG. 1, the geologic environment 150 may include layers (e.g., stratification) that include a reservoir 151 and one or more other features such as the fault 153-1, the geobody 153-2, etc. As an example, the geologic environment 150 may be outfitted with any of a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a well site and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite in communication with the network 155 that may be configured for communications, noting that the satellite may additionally or instead include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

As mentioned, the system 100 may be used to perform one or more workflows. A workflow may be a process that includes a number of worksteps. A workstep may operate on data, for example, to create new data, to update existing data, etc. As an example, a may operate on one or more inputs and create one or more results, for example, based on one or more algorithms. As an example, a system may include a workflow editor for creation, editing, executing, etc. of a workflow. In such an example, the workflow editor may provide for selection of one or more pre-defined worksteps, one or more customized worksteps, etc. As an example, a workflow may be a workflow implementable in the PETREL® software, for example, that operates on seismic data, seismic attribute(s), etc. As an example, a workflow may be a process implementable in the OCEAN® framework. As an example, a workflow may include one or more worksteps that access a module such as a plug-in (e.g., external executable code, etc.).

### Operational Solution Framework: Leveraging Machine Learning and Natural Language Processing for Automatic Well Test Validation

The present disclosure addresses the challenges associated with handling a high volume of well tests daily such as incorporating information from operational activities, and especially, potential delays and errors in validation impacting other dependent business processes. The present disclosure aims to reduce processing time, minimize human error, and enhance accuracy in a well test analysis. Having up-to-date and reliable well test data, engineers can improve engineering workflows, and optimize production.

The present disclosure covers data consumption, data preparation, and machine learning (ML) solutions. It also cooperates with dependent business processes, deployment, and retraining strategies. The ML solution learns from historical well test data with accepted and rejected flags to build a rule-based deterministic ML model to automatically validate and detect the invalid well test with probability. The solution consumes structure data and textual data with natural language processing (NLP), such as well test comments provided by well testing engineers and operational activities in daily operational reports (DORs). Data consumption, operational activities, and/or dependent workflow control may be customizable based on different projects. The retrain strategy may be based on model prediction accuracy trends and defined during deployment. The solution triggers insights with confidence scores, suggesting acceptance/rejection or review of new well tests. Early detection of possible rejections enables timely actions, including retesting if applicable.

The solution reduces well test validation time from weeks to hours, enhancing the accuracy of production analysis and optimizations. The data-driven approach offers flexibility and adaptability to meet operation standards, presenting a robust alternative to rule-based validation. By integrating ML and NLP, the solution provides a comprehensive and efficient framework for well test validation, improving decision-making and ensuring compliance with standard operation procedure (SOP).

Thus, the present disclosure provides an approach to well test validation by leveraging ML and NLP. By considering both historical data and manual operational event inputs from engineers, the solution enhances the accuracy and efficiency of the validation process. It contributes to improved production performance analysis, diagnostics, and issue detection. The solution deployment can be customized and adaptable to different data storage and availability, to automate well test validation processes in the oil and gas industry.

The present disclosure uses the integration of machine learning (ML) and natural language processing (NLP) to enhance well test validation. ML has the capability to discover patterns and relationships within well test data, automating the identification of valid measurements while highlighting anomalies. Simultaneously, NLP assists in extracting insights from textual information such as remarks and operational reports, thereby expediting the validation process.

A comprehensive operational framework is introduced herein. The framework encompasses data collection to the utilization of AI tools, culminating in the presentation of results through an engineer-friendly interface. One goal of this framework is to facilitate auto/informed decision-making.

By harnessing the potential of ML and NLP, the proposed approach aims to elevate the accuracy, efficiency, and reliability of well test validation. The envisioned outcome includes a reduction in manual labor, a decrease in errors, and the provision of more profound insights into well performance. Ultimately, this advancement could pave the way for improved decision-making, reinforced reservoir management, and optimized production operations within the oil and gas sector.

### Operational Framework

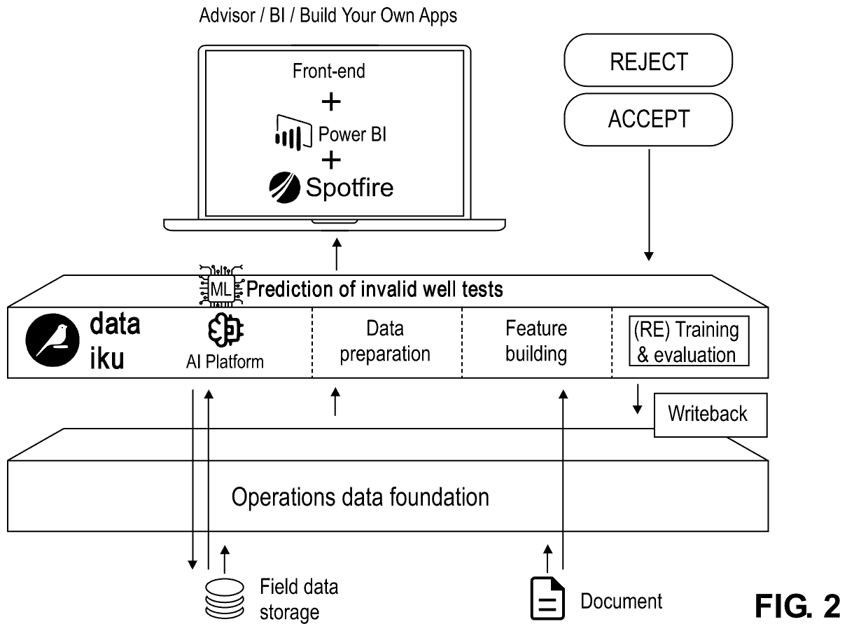

FIG. 2 illustrates an operational framework and data flow, according to an embodiment. One method includes developing a proficient ML model by harnessing diverse ML algorithms and NLP techniques. The chosen ML model is now prepared for deployment in a production environment.

Newly acquired well test data, DORs, and/or deferment activities may be seamlessly integrated into the production data foundation, or through customer field data store. The recently collected well test data and its corresponding relevance undergo may be preprocessed using the established standard in data preprocessing. Subsequently, the ML model utilizes this refined data for automated and informed validation.

A user-friendly interface has been pre-built to streamline the flow of well test data, providing a dedicated well test validation summary, a comprehensive data table, and property trend plots with events and operational activities in one place to assist user for decision making. While the predictions made by the ML model can serve as the default, users are empowered to exert their own judgment and potentially overwrite these predictions. In instances where the ML model detects an invalid well test, a user-driven manual validation process may be used prior to initiating a new well test order, considering the associated costs.

The conclusive validation decision, whether influenced by user input or the ML model's insights, may be made and is then stored within the production data foundation or the designated customer field data store. This user-driven feedback loop is a valuable and exclusive asset for any ML model. In comparison to models that are resource-constrained, this nature has an advantage in terms of continuous learning and improvement over time.

Model performance may be monitored and logged continuously. When model performance wanes, the ML model undergoes retraining and updates to ensure its continued accuracy and relevance.

### Solution Framework and Deployment

The solution and deployment of well test validation encompass the following components:
Integration with field data storage: creating a seamless link to the data store, ensuring access to relevant well test and operational information.
Extraction of well test and relative operational information: extracting well test data, operational events, deferments activities from the connected data store for further analysis.
Activation of AI: developing ML models tailored for well test validation.
Deployment and monitoring of ML models: deploying ML models and continuously monitoring their performance.
Auto/Informed decision-making with ML predictions: incorporating ML predictions to facilitate automated or informed decision-making.
Visualization and streamlined manual well test validation: implementing visualization tools and efficient manual validation capabilities to streamline the validation process.
Regular model maintenance: ensuring the ongoing maintenance and optimization of ML models.

This comprehensive framework seamlessly integrates ML capabilities into the well test validation process, enhancing the efficiency of validation, enabling automated or informed decision-making, and facilitating adaptable model maintenance. Detailed discussions of each component's application in the field context are provided in the following discussion. Furthermore, this solution framework is easily extendable to other oil and gas fields, showcasing its versatility and potential for widespread adoption.

Integration with Field Data Storage

Establishing a robust data store connection may help to provide effective well test validation, but this endeavor presents challenges. One common challenge involves the integration of data from multiple unrelated sources, including multiphase meters, separators, and operational reports. Ensuring the seamless flow of data from these diverse origins involves careful data mapping, transformation, and alignment. Furthermore, addressing the challenge of maintaining data consistency and quality may help to reduce errors or discrepancies, which can undermine the accuracy of the validation process.

To tackle these challenges, the process starts by establishing a seamless connection to the field data storage system. In this context, a pre-built production data store resides on the cloud with a predefined schema of entities, properties, and relationships for streamlined data mapping and ingestion. This data store offers a unified solution, utilized across the sections, domains, platforms, fields, workflows, and applications that build on top of it. Users also have the flexibility to directly connect to the field data storage, managing entities, properties, units, and relationships separately.

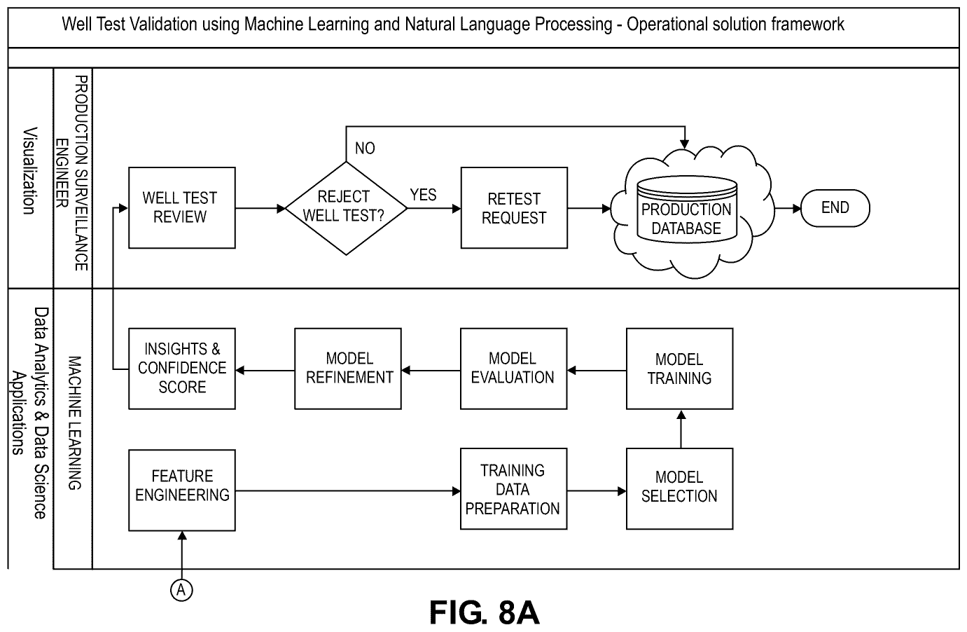

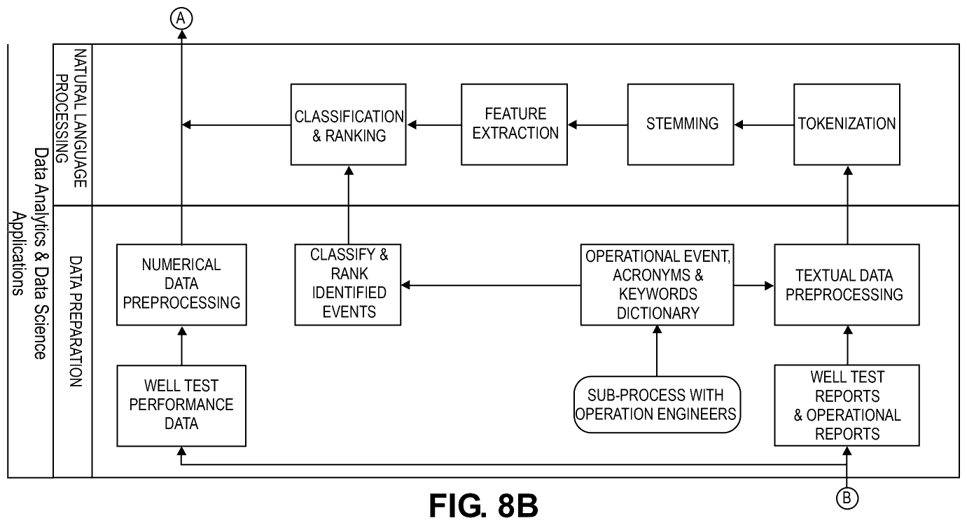

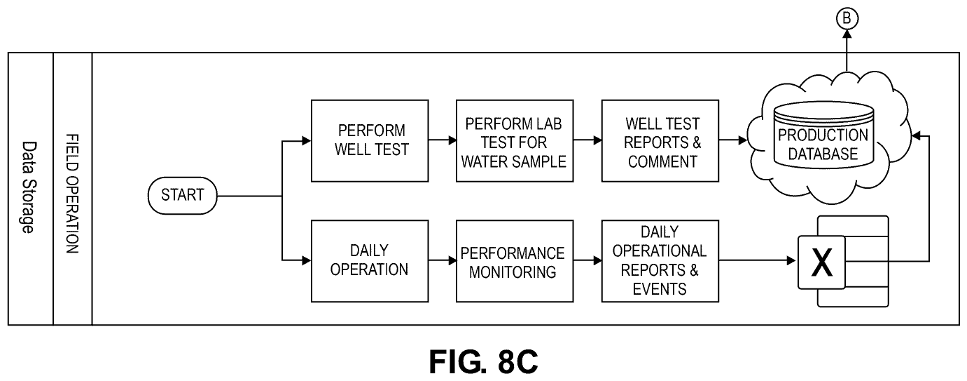

In the specific context of a customer, a connection to the company centralized production database may be used to access the latest raw well test parameters and to write back validation results to the same database. Concurrently, DORs in spreadsheet format, provided by offshore operational staff, serve as sources of information for engineers to gain insights into operational performance. By navigating these challenges and leveraging these data connections, the well test validation process gains the foundation needed to succeed (e.g., data storage section in diagraph in FIGS. 8A-8C). This comprehensive approach simplifies data retrieval and lays the groundwork for employing advanced techniques like ML and NLP for automated validation. Ultimately, a well-constructed and well-maintained data store connection ensures that the validation process is founded on accurate, reliable, and current data, contributing to enhanced accuracy, efficiency, and well-informed decision-making in assessing well performance.

### Extraction of Well Test and Relative Operational Information

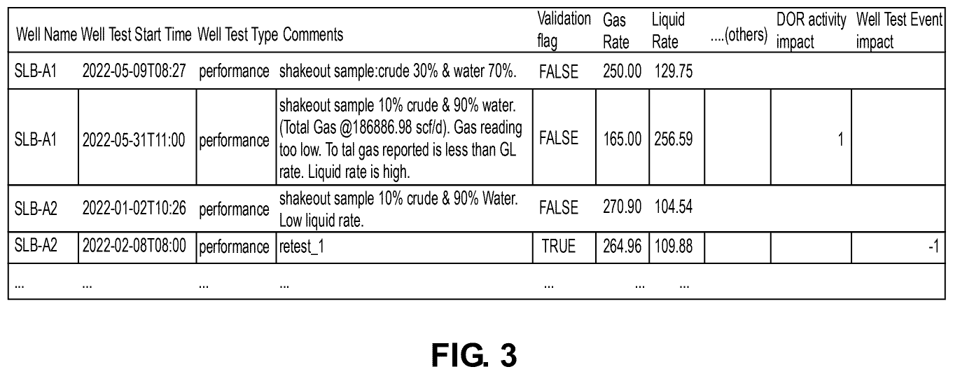

The comprehension of the well test validation process and its criteria may be used by data scientists and data engineers. A well test report serves as a tool for capturing observations and ensuring comprehensive documentation of the well testing process. From the well test report, engineers may extract details, including various well test types, relevant parameters, attributes associated with well tests, operational activities, and predetermined events. FIG. 3 illustrates a comprehensive table that encompasses the well test parameters used for validation, according to an embodiment. The table features manual validation flags, well test comments, and designates the well test type (e.g., well performance test and multi-rate test). The table may be used in the field application context. FIGS. 8A-8C illustrate a detailed workflow of numerical data and textual data preprocessing, according to an embodiment.

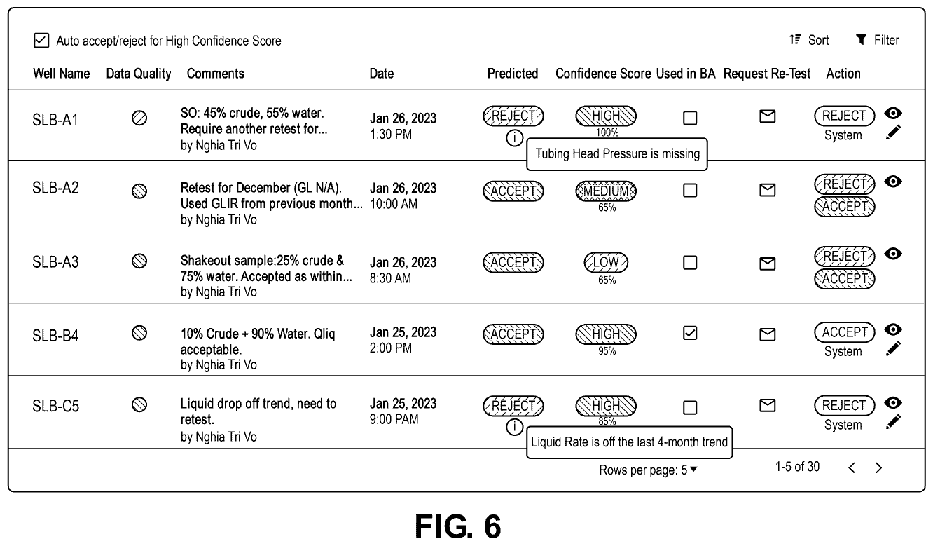

Preprocessing of numerical data may be used to ensure the integrity of the dataset by eliminating well tests with insufficient data, removing duplicate information, and handling unit conversions. The determination of predetermined data may be carried out by the operation team and may vary across different fields or operators. In case any mandatory data is found to be missing, the entire well test sample may be directly categorized as an invalid well test, and the user may see details of what data is missing on the frontend, as shown in the first row of FIG. 6. For non-mandatory data that is missing, well tests may continuously be processed. If it is during the ML training process, a strategy of infilling with previous carry forward values may be employed. This approach applies to data elements such as well head choke size, manifold choke size, THT, BHT, and other relevant parameters. Each type of data has its validation range pre-defined, and any data falling outside this range may be identified as an outlier and subsequently removed.

Information may be extracted from unstructured textual data to standardize as feature input in ML. Beside numerical data, well test report also has manual textual input from operation team containing valued data such as oil sample lab test results, emulsion detection, measurement erroneous, well stability during well test period, and the like. By utilizing the well test comment section, the operation staff responsible for the well test can communicate information, share insights, and document any pertinent details that may impact the interpretation and validation of the test data.

In additional, a daily operational report (DOR) in the oil and gas industry is a daily document summarizing operational activities and metrics. It covers production data, drilling progress, safety incidents, equipment status, logistical information, personnel updates, external factors, and financial performance. Well related operational activities are also captured daily in DOR. Some of them may lead to well performance changes and new tests off the trend, such as gas lift valve change (GLVC), production zone change, acidizing job, flow direction change to high-pressure separator (HPS) or low-pressure separator (LPS), replace new X-mass tree, well reactivation, stop gas lift and many other categories. Textual format information may be extracted and standardized as input features in ML.

To extract events from both well test comments and operational remarks in the oil and gas industry, collaboration with the engineers responsible for documenting the information is recommended. This collaboration may help to fully comprehend the nuances and meanings embedded within the textual input. Particularly, engaging with engineers may help to gain an understanding of certain terms, phrases, and technical jargon that may be unique to the company's operations. This includes specific operational device names and acronyms that might not be readily understandable without context. The engineers' expertise can provide valuable insights into the context and implications of these terms, enabling accurate and meaningful event extraction. This cooperative approach ensures that the extracted information maintains its integrity and accurately reflects the operational activities and events being described, the outcome of which is the list of reported event words for NLP to learn from.

### NLP on Well Test Comments and Operational Remarks

Conventional hard-coded word searches may be ineffective due to the various ways of expressing the same concepts, making it difficult to list the possible variations. To address these challenges, regular expressions may be utilized to identify and replace using patterns with predefined words, ensuring standardization. Values extracted from the text may be saved as extra measured properties and used for feature building. For instance, the value of sample Bsw (basic sediment and water) represents water cut measured from lab, may be extracted from well test comment.

When translating activity or event type of comments into classifications, it becomes useful to determine whether an action has already been performed or is planned by analyzing verb inflections (e.g., present, past, or future tense). For example, well test type classification may be accomplished through NLP-based word searches. Whenever base words such as MRT (multi-rate test) are found as an action happen in the past, the corresponding well tests may be identified as special tests, while the well test validation process may focus (e.g., exclusively) on regular production performance tests.

Within the field application, operational activities may be extracted through NLP techniques from DORs. These activities may be subsequently categorized into distinct groups based on their impact levels (e.g., No impact-“0”, Positive impact-“1”, Negative impact-“−1”) on well test validation. Moreover, unique events such as sand production, emulsion occurrences, high water production issues, transitions to low-pressure pumps, and measurements after Christmas tree installations can also be categorized based on their impact on well test validation. The collected information relevant to well tests can be succinctly summarized in the provided in the table in FIG. 3. If operational activities and events are systematically categorized and stored within the database, the process of regrouping them based on their impact on validation becomes notably more streamlined.

### Activation of AI

To activate the AI solution, data scientists and data engineers may acquire a predetermined volume of historical data with validation flag(s) for the training and evaluation of the ML model during development. A specific ML model can be developed on one field or a plurality of similar fields depending on the well counts, well test data quality, and availability. There is similarity in terms of similar validation policy, data type, field type, and maturity.

ML model development may include several processes: data preprocessing, feature building, model training and evaluation, model selection, validation, and deployment (see diagraph FIG. 8A ML section). Data preprocessing is discussed above. In general, feature engineering refers to domain knowledge and data analytics techniques used to include or reduce the number of features in a dataset. In feature extraction, new features are created from the existing ones to enrich the representation and knowledge, and a subset of these new features is used to replace the original features. These selected features may be able to represent the most relevant information from the original data and domain knowledge. Time series and variable correlation analyses may be performed prior to feature building. Once the time series is rolling, it may be meaningful to compare and correlate with valid well tests and exclude previous invalid tests. Based on the correlation and lag feature analysis, time series decomposition features may be built including statistic-based features such as average, standard deviation, mean, and rate of changes, as well as correlation-based features, such as the correlation between pressure change and rate change or pressure changes at different locations. Additionally, domain-based features, including operational activities, well test comments, and laboratory comments, may be incorporated. In an example, a total of 472 features may be created initially, and the importance of each feature may be evaluated to access the prediction power on target. Continuing with the example, after the model is refined, feature reduction, a final set of selected features may contain less than 150 components for training and testing.

Supervised learning with labeled data may be used to detect invalid well tests. For training and evaluating performance, the samples may be divided into training and testing datasets (e.g., using an 80/20 split randomly). Various ML classification algorithms: random forest, logistic regression, XGBoost, decision tree, and/or SVM algorithms may be utilized for training and performance comparison. Optimizations with an F1 score and weighted cost functions may be pre-set during model training. The performance results may then be ranked, and the best performing ML model may be selected. From domain point of view, the omission of invalid well tests may have an impact compared to other performance matrices. If the model fails to identify invalid well test and lets it go into the system, it could potentially damage other workflows as discussed above. Therefore, recall may be weighted more than others. In the field application, a recall score of 70%, F1 score of 71%, precision of 73%, and accuracy of 87% may be achieved. In an embodiment, random forest and decision tree methods may present the highest F1 score among other algorithms.

### Deployment and Monitoring of ML Models

Organization hierarchies and relationships can be set up for authority and data management. The most refined ML model may then be deployed to wells, under specific field(s) or attribute(s) in the hierarchy. By mapping ML models according to hierarchy attributes, it becomes possible to deploy multiple ML models to predict performance across different wells. The data may be preprocessed in a similar way to training data. This may involve cleaning, transforming, and encoding the features.

During the deployment process, manual or automatic validation may be performed with the pre-build-in template for over 100 raw well tests within a couple months. This allows for cross-checking the accuracy and stability of the ML model, adjusting or retraining the model with latest data to achieve acceptable standards in terms of recall, F1-score, and/or accuracy. This refining and validation process also gives insight for user defined confidence thresholds (e.g., high, medium, and low) within auto-validation setting. Rigorous validation ensues, employing the most up-to-date user validation data for comparison and monitoring to ensure optimal performance, so that user can turn on auto decision making mode with trust.

Auto/Informed Decision-Making with ML Predictions

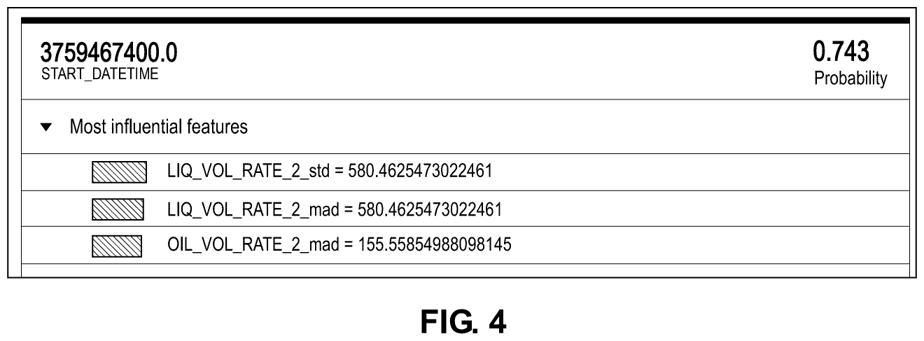

FIG. 4 illustrates a Shapley interpretation to explain features that contribute to prediction of an ML model, according to an embodiment. ML predictions play a pivotal role in assisting and automate users' decision-making regarding the acceptance or rejection of well tests. ML prediction with confidence (e.g., based on probability) may be available under the well test table for each newly conducted well test. Users can perform manual checks and refer to a ML model's outcome to make accurate and reliable decisions. For example, a user's initial decision may be to accept the well test, while the ML model gives the opposite suggestion. Users can refer to Shapley interpretation results (see FIG. 4) to understand why the model decides to reject the test and what are the features contributing to the model's decision that might not be considered during user's assessment.

An auto-decision making configuration may be designed to automate the ML model's decision using a confidence score threshold. Once the Auto-decision is on, any predicted decision with high confidence score may be automatically set to use by system without human intervention. Meanwhile, the ones with low and/or medium confidence may request a user's action to determine the validity of the test data. For the accepted well tests, a Valid=TRUE flag may be written to the data source, and well test data may be ready to be used as input to other workflows. For the wells with the rejected well tests, a well test Valid=FALSE flag may be written to the data source, and an action of requesting for retest may be sent out to testing team. This minimizes manual intervention, allowing users to focus their efforts on reviewing a few well tests with low confidence.

### Visualization and Streamlined Manual Well Test Validation

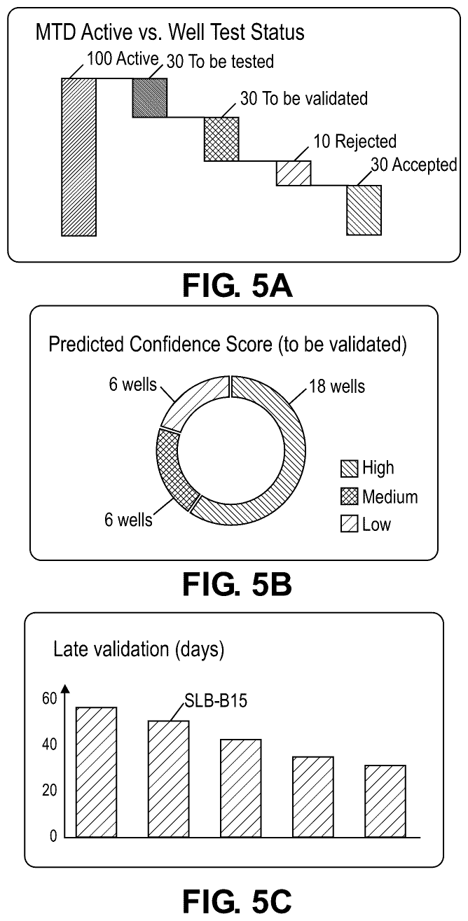

FIG. 5A illustrates a well test validation summary including MTD active vs. well test status, FIG. 5B illustrates a well test validation summary including a predicted confidence score (to be validated), and FIG. 5C illustrates a well test validation summary including a late validation notification, according to an embodiment. A user-friendly interface may be pre-built to streamline the flow of well test data, providing a dedicated well test validation summary, a comprehensive data table, and property trend plots.

More particularly, a waterfall chart (FIG. 5A) serves to summarize the expected number of well tests to be conducted, correlating with the total active wells for the month. This chart further offers insights into the total number of wells tested, accepted, rejected, requiring validation, and those remaining for testing. In FIG. 5B, the donut chart summarizes a predicted confidence score for to-be-validated wells, in which high confidence scored wells are recommended for auto-acceptance or auto-rejection, aiming to reduce the verification time required by engineers. This bar chart month-to-date (MTD) information and ranked late validation wells (FIG. 5C) aids engineers in promptly identifying remaining to-be-validated wells to ensure compliance with company and regulatory standards.

FIG. 6 illustrates a well test validation table, according to an embodiment. Engineers may be provided access to the most recent well test attributes within a customizable timeframe through the well test table (depicted in FIG. 6). This table includes data quality indicators, well test comments, and the option to apply these attributes to other workflows, such as production back allocation. Within this table, users can promptly identify data discrepancies using detailed statements. The table also presents validation outcomes generated by the ML model, offering confident scores and explanations for root causes to aid decision-making. Engineers maintain the capability to further engage by approving or rejecting each well test. With auto-decision making function turned on, users can efficiently filter well tests based on actions, prioritizing manual intervention for specific cases. During the initial months of solution deployment, it may be recommended that engineers adopt a manual process (e.g., with auto-accept/reject functionality disabled) to establish confidence in the predictive recommendations generated by the AI-backed backend process. This approach also allows time for validation and refinement of the deployed ML model to achieve optimal performance.

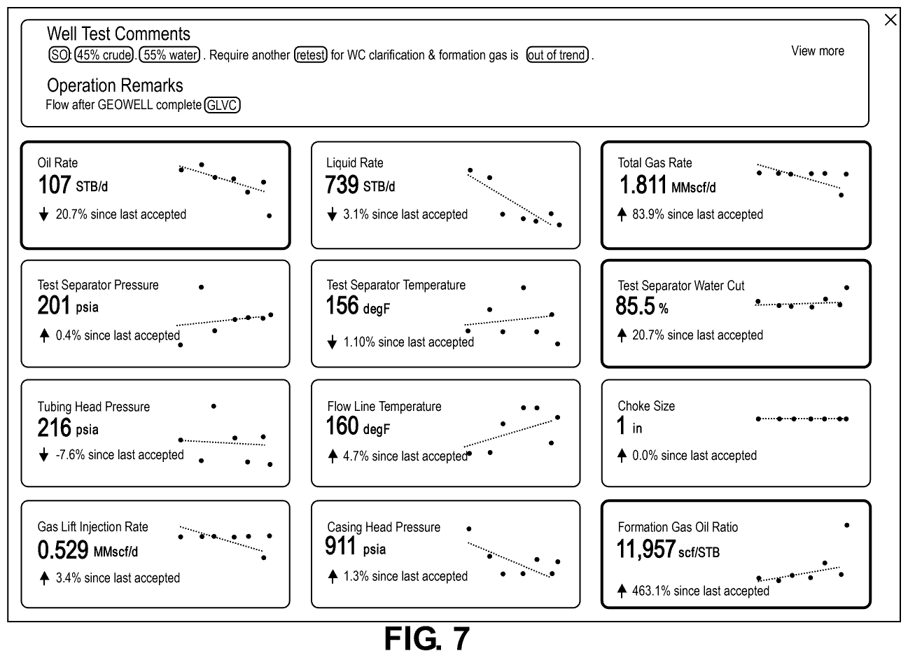

FIG. 7 illustrates well test comments, operational remarks, and well test trend plots with notifications, according to an embodiment. To enhance the efficiency of manual validation, users can leverage the insights provided by the ML model, complete with root cause interpretations (refer to FIG. 6) and utilize the readily available well test property trend plots (depicted in FIG. 7). These tools serve to direct their focus towards prominent trends, operational events, predetermined occurrences, and instances of conflicting measurements, thus accelerating well-informed decision-making. In cases where current measurements diverge from established trends by more than a predetermined threshold, the property trend plot may be dynamically highlighted, promptly alerting users to potential anomalies. To further emphasize textual data, like well test comments, users have the option to apply user-defined words based on specific equipment name, event name, and so on for extended word search, thus providing prompts. Additionally, when users opt to expand their view, the interface presents operational activities and noteworthy events that have transpired between the current and last validated well tests. This comprehensive interface effectively empowers engineers, enabling them to conduct well test validation efficiently and with an elevated level of accuracy.

### Regular Model Maintenance

Regular model maintenance may help to ensure that the ML models continue to perform well over time as new data becomes available. One aspect of model maintenance is the retraining strategy, which involves periodically updating the model using new data. In instances where the ML model's accuracy wanes, its usage duration may be extended, or policies undergo changes, the model may benefit from retraining and updates. In the field application, a general outline of a regular model retraining strategy is described next. Once it passes the first 2-3 months of the validation period, the planned retraining schedule may be every 3 months in general. At the same time, model prediction recall and F1 score on new data may be logged and compared with the baseline performance on validation dataset. Alarms may be triggered once the prediction recall and F1 score falls a predetermined amount (e.g., 10%) below the baseline thresholds, and model may be updated with new data or re-evaluated on a feature set. Two-way communication between data scientists, domain users, and engineers may help users to learn and establish healthy habit to avoid inconsistency decision making and human errors. Feedback from users and domain experts regarding the quality of the model prediction may provide the insight for potential performance issues, including creating new features or updating existing ones.

The operational framework described herein proves its utility. This includes establishing a seamless connection to the data store, thereby granting access to valid well test and operational data. The framework involves the extraction of well test information, along with relevant operational events and deferment activities, from the connected data store for subsequent analysis. By integrating tailored ML models, the framework enables precise well test validation. These models may then be deployed and continuously monitored to ensure optimal performance. The framework further facilitates decision-making by incorporating ML predictions for automated or well-informed choices. Visualization tools and efficient manual validation capabilities may be implemented to streamline the validation process. Regular model maintenance may be a core component, ensuring the ongoing optimization and upkeep of the ML models, solidifying the framework's practicality and effectiveness. As this well test validation process has a user feedback loop (e.g., accept and/or reject well test), this nature has an advantage in terms of continuous learning and improvement over the time. Additionally, the framework standardizes the method of data input and the capturing of comments/remarks, thereby enhancing consistency and clarity across the board.

FIGS. 8A-8C illustrate an operational solution framework, according to an embodiment. Beyond the incorporation of ML and NLP capabilities, the path ahead offers an opportunity to amplify operational efficiency. Enabling engineers to input new or modify existing operational event words from the user interface as novel field operations unfold creates a dynamic and adaptive system. This collaborative approach leverages the collective expertise of operational teams, ensuring accurate recognition of emerging events. This iterative engagement enhances event interpretation and cultivates user ownership and active participation in refining operational processes. This user-driven word update integration becomes a vital part of the framework, embodying the commitment to continuous improvement and real-world responsiveness.

Consistent evaluation of producers' performance and productivity through production performance well tests may be beneficial. The role of well test data as a foundational input for numerous workflows underscores desire to standardize the well test validation process and ensure its timeliness and accuracy. To address these challenges, an AI-driven solution framework has been introduced, seamlessly integrating well test and operational information collection into the production database. Harnessing the power of data analytics, data science, ML, and NLP, this solution enhances the well test validation process.

The solution framework may be constructed into an operationalized structure, featuring a user-friendly interface that fosters an efficient user feedback loop. The incorporation of ML models that are consistently updated over time further elevates the accuracy and efficiency of well test validation. Tangible benefits emerge for the oil and gas industry by automating well test validation through the incorporation of ML and NLP capabilities. The process quickly identifies errors and anomalies within extensive well test data, spanning numerical and natural language domains. This uplifts data quality, thereby empowering robust decision-making and facilitating data-driven workflows that curtail operational expenditures.

Beyond efficiency gains, the solution framework contributes to risk mitigation, regulatory compliance, and the ongoing enhancement of production processes. ML algorithms reveal concealed patterns and correlations, offering optimization prospects for production, well performance, and reservoir management. NLP, on the other hand, extracts textual information, enriching the collective knowledge base and sustaining future validation endeavors. By harnessing the capabilities of these cutting-edge technologies, organizations can fully capitalize on the value of their well test data. This standardized work process translates into streamlined operations, sustainable growth, and a great impact on the trajectory of oil and gas industry.

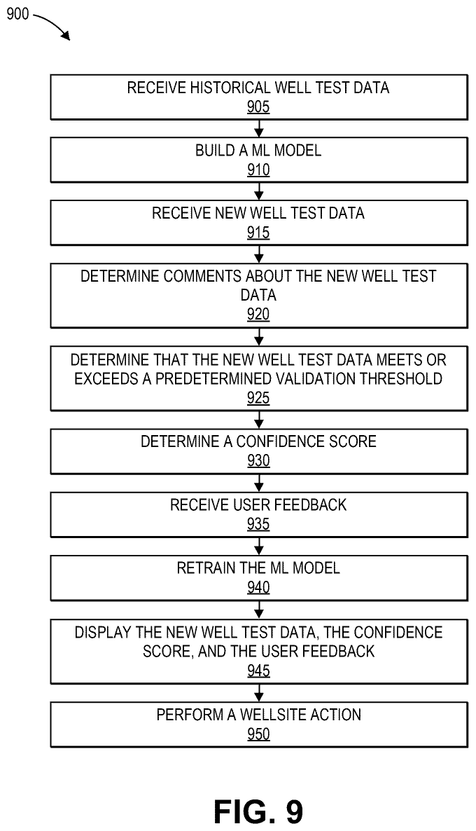

FIG. 9 illustrates a flowchart of a method 900 for validating a well test, according to an embodiment. An illustrative order of the method 900 is provided below; however, one or more portions of the method 900 may be performed in a different order, simultaneously, repeated, or omitted.

The method 900 may include receiving historical well test data, as at 905. The historical well test data may include one or more accepted flags and one or more rejected flags.

The method 900 may also include building a machine-learning (ML) model based upon the historical well test data, as at 910. The ML model may be a rule-based deterministic ML model.

The method 900 may also include receiving new well test data, as at 915.

The method 900 may also include determining comments provided by a first user about the new well test data, as at 920. The comments may be determined using a natural language processing (NLP) engine.

The method 900 may also include determining that the new well test data meets or exceeds a predetermined validation threshold using the ML model, as at 925. The determination may be at least partially based upon the comments.

The method 900 may also include determining a confidence score that the new well test data meets or exceeds the predetermined validation threshold, as at 930.

The method 900 may also include receiving user feedback from a second user regarding the new well test data meeting or exceeding the predetermined validation threshold and the confidence score, as at 935.

The method 900 may also include retraining the ML model based upon the user feedback, as at 940.

The method 900 may also include displaying the new well test data, the confidence score, and the user feedback, as at 945.

The method 900 may also include performing a wellsite action, as at 950. The wellsite action may be based upon the new well test data meeting or exceeding the predetermined validation threshold, the confidence score, and/or the user feedback. The wellsite action may be or include generating and/or transmitting a signal (e.g., using a computing system) that causes a physical action to occur at a wellsite. The wellsite action may also or instead include performing the physical action at the wellsite. The physical action may be or include performing the well test again (i.e., retesting). The physical action may also or instead include varying a weight and/or torque on a drill bit, varying a drilling trajectory, varying a concentration and/or flow rate of a fluid pumped into a wellbore, or the like.

### Automatic Well Test Validation Using Machine-Learning and Natural Language Processing

The present disclosure aims to reduce the processing time to gather historical information to validate the information with engineering models. The present disclosure also limits human error by checking the available well tests and preparing detailed analyses for engineers to make a final decision. By having more updated accepted well tests to update well engineering models, the present disclosure helps to improve accuracy and create more confident outputs in other engineering workflows such as production back allocation, well rate estimation, well and network model calibrations, and production optimization.

The present disclosure leverages artificial intelligence (AI) capability, which learns from historical well test data with accepted and rejected flags, to build a rule-based deterministic machine learning (ML) model. The model may automatically validate and detect the possible rejected or accepted well test. The present disclosure also considers well test comments or remarks provided by well-testing engineers which are processed via a Natural Language Processing (NLP) engine. The ML model can propose to accept a well test with a confidence score to automate the validation and support engineer's decision. On the other hand, if the model detects a possible rejected well test, it suggests that the engineer review the new well test information versus historical performance. Early rejection triggers retesting by the offshore team to prioritize the well to the test plan. Periodically, the ML model may involve updates based on the most recent well test data in order to maintain its accuracy.

The present disclosure reduces the well test validation time from weeks to hours. It also improves the accuracy of other production performance analyses and optimizations. The data-driven approach can easily be adapted to different fields', thereby offering a more flexible and efficient alternative to hard-coded rule-based well test validation.

The present disclosure proposes a more advanced approach that leverages machine learning and natural language processing techniques to enhance the well test validation process. Machine learning algorithms can be trained to recognize patterns and relationships in well test data, enabling automated identification of valid measurements and flagging potential anomalies. Natural language processing techniques can aid in interpreting and extracting relevant information like remarks and comments from well test and daily operational reports which are manually captured by operation teams, further facilitating the validation process.

By applying machine learning and natural language processing, the proposed approach aims to improve the accuracy, efficiency, and reliability of well test validation. It has the potential to reduce manual effort, minimize errors, and provide more meaningful insights into well performance. Ultimately, this can lead to better decision-making, improved reservoir management, and optimized production operations in the oil and gas industry.

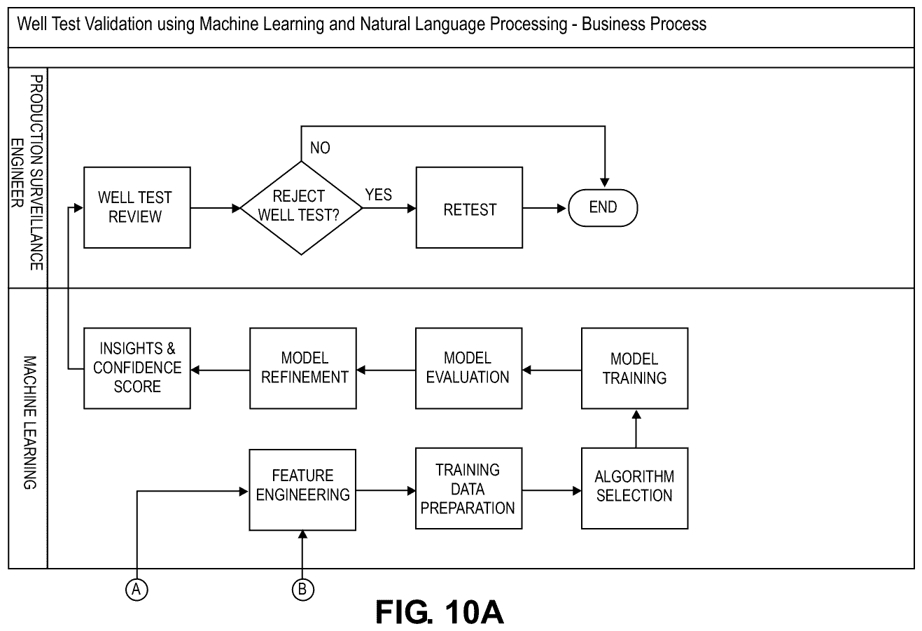

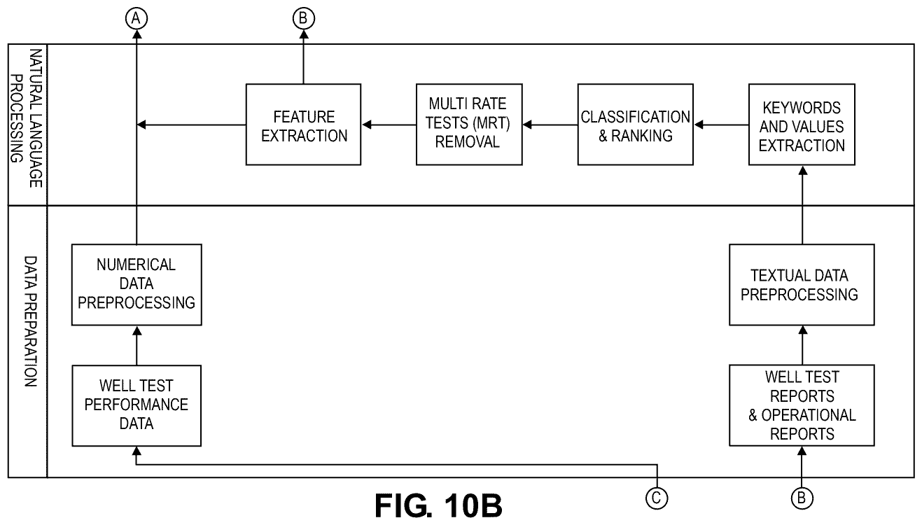

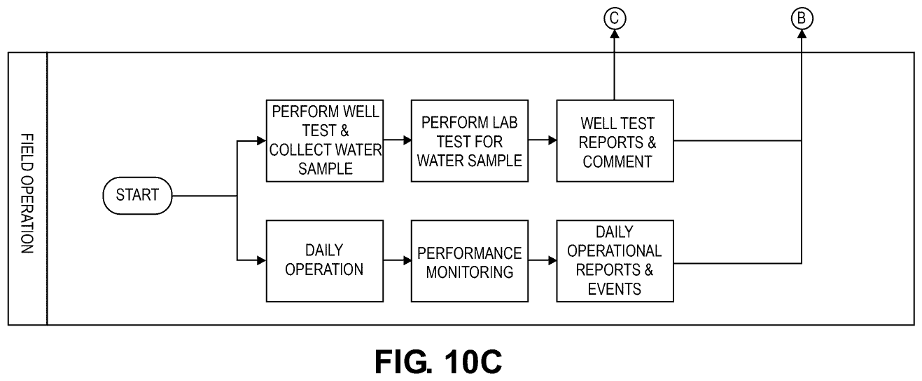

FIGS. 10A-10C illustrate a flowchart showing well test validation using machine learning and natural language processing, according to an embodiment. Production well testing refers to the process of evaluating the performance and productivity of a well by conducting various tests to measure its flow rates, pressures, and other parameters. These tests provide valuable data and insights into the behavior of the reservoir, the efficiency of production operations, and the overall performance of the well.

One type of well test is the well performance test. It involves measuring the flow rate of fluids (such as oil, gas, or water) produced from the well under specific operating conditions. The purpose of a well performance test is to determine the well's deliverability, which is the maximum rate at which it can produce fluids. This test helps in estimating the well's production potential, evaluating reservoir characteristics, and optimizing production strategies.

Another type of well test is the multi-rate test. In a multi-rate test, the flow rate is varied at different levels over a specified period. This test allows for the assessment of the well's behavior under different production rates and helps in determining reservoir properties such as permeability, skin factor, and reservoir pressure. By analyzing the pressure and rate data obtained during a multi-rate test, engineers can gain insights into the reservoir's response to different production scenarios and make informed decisions regarding well operations and optimization.

Besides well performance tests and multi-rate tests, other performed well tests include buildup tests, falloff tests, interference tests, and injectivity tests. Each of these tests serves a specific purpose in evaluating different aspects of well and reservoir behavior, such as reservoir pressure, permeability, and connectivity.

Overall, production well testing plays a role in the oil and gas industry by providing essential data for reservoir characterization, well performance assessment, and optimization of production operations. These tests help in understanding reservoir dynamics, improving productivity, and maximizing hydrocarbon recovery.

In well test analysis described herein, a comprehensive set of data parameters is utilized to assess the performance and behavior of the well. Examples of these parameters are listed in Table 1.

TABLE 1
Well test parameters

| Parameter | Descriptions | Unit |
|---|---|---|
| Basic sediment and | The measured percentage of water | % |
| water (Bsw) | present in the produced fluids | |
| | via sample | |
| Bottom hole pressure | The pressure measured at the | psia |
| (BHP) | bottom of the wellbore | |
| Casing head pressure | The pressure at the wellhead | psia |
| (CHP) | at the level of the casing | |
| Flow line temperature | The temperature at the flow | ° F. |
| (FLT) | line after production choke | |
| Formation Gas Oil | The ratio of gas to oil present | Mscf/bbl |
| Ratio (FGOR) | in the reservoir formation | |
| Gas lift choke | The adjustable valve used to | inch |
| | control the injection rate | |
| | of gas lift | |
| Gas lift injection | The rate at which gas is injected | Mscf/D |
| rate (GLIR) | into the wellbore for gas lift | |
| | operations | |
| Gas production rate | The rate at which gas is produced | Mscf/D |
| | from the well | |
| Liquid production rate | The total rate at which liquids | bbl/D |
| | (oil and water combined) are | |
| | produced from the well | |
| Oil production rate | The rate at which oil is produced | bbl/D |
| | from the well | |
| Production choke | The adjustable valve used to control | inch |
| | the flow rate of production fluids | |
| Separator pressure | The pressure at which the produced | psia |
| (Psep) | fluids are separated into their | |
| | respective phases (gas, oil, water) | |
| Separator temperature | The temperature at which the | ° F. |
| (Tsep) | produced fluids are separated | |
| Total gas production | The total rate at which gas is | Mscf/D |
| rate | produced from the well plus gas | |
| | lift injection rate | |
| Tubing head pressure | The pressure at the wellhead at | psia |
| (THP) | the top side of the tubing before | |
| | production choke | |
| Water cut | The calculated percentage of water | % |
| | present in the produced fluids | |
| Water production rate | The rate at which water is | bbl/D |
| | produced from the well | |
| Well test comment | Any additional comments or notes | |
| | related to the well test | |
| Well test status | The classification of the test, | |
| | whether it is newly conducted, | |
| | accepted, or rejected well test | |
| Well test type | Specifies the type of well test data, | |
| | whether it is measured directly, | |
| | corrected for specific factors, or | |
| | estimated based on other data | |

By analyzing and interpreting these diverse parameters, a comprehensive understanding of the well's performance, production characteristics, and potential optimization opportunities may be obtained.

As mentioned above, the conventional approach to validating well test data involves a combination of workflow-based validation, manual validation, knowledge from the operation team, and especially, the actual operation taken place at the field. However, it is not easy to gather these in one place to make the final decision.

Workflow-based well test validation relies on predefined workflows and rules to validate the data. This approach may use different thresholds or criteria for different wells, which can be challenging to define accurately. Additionally, this method often lacks flexibility in adapting to changing well conditions or variations in data patterns. Moreover, maintaining up-to-date operational data and models for workflow-based validation can be costly and time-consuming.

Manual well test validation heavily relies on human expertise and judgment to assess and validate the data. While this approach allows for more flexibility and adaptability, it is susceptible to errors and inconsistencies due to human factors. Manual validation can be time-consuming, especially when dealing with large volumes of data, and it may not scale well for complex well systems or extensive data analysis.

Knowledge from the operation team can provide valuable insights and contextual understanding of the well test data. However, this approach heavily relies on the availability and accuracy of shared information. It can be challenging to capture and retain the collective knowledge and experience of the team, especially when there is a high turnover rate or limited documentation.

Another piece of information to validate well test data is by comparing it to the actual operations and measurements taken at the field. This method involves monitoring and analyzing the real-time operational data, such as flow rates, pressures, and temperature, directly from the wellsite. Another element that can contribute to the validation process is the daily operational report (DOR) that keeps track the operational events happening to the well. The difficulties are sensor calibration, data historian reliability, and the consistency of event tracking.

To overcome these drawbacks, alternative approaches may be used that leverage technology and automation. Machine learning and advanced data analytics techniques can be employed to enhance well test validation. By developing physics-based well models and utilizing historical and real-time data, these approaches can provide more accurate and efficient validation, reducing the reliance on manual efforts and extensive maintenance costs. Furthermore, by automating the validation process, these methods can improve scalability, consistency, and adaptability while reducing the potential for human errors.

Preprocessing of the data may help to ensure the integrity of the dataset by eliminating well tests with insufficient data, removing duplicate information, and handling unit conversions. The determination of mandatory data may be carried out by the operation team and may vary across different fields or operators. In case any mandatory data is found to be missing, the entire well test sample may be directly categorized as an invalid well test with an ‘insufficient data’ flag. For non-mandatory data that is missing, a strategy of infilling may be employed that uses previous carry forward values. This approach applies to data elements such as well head choke size, manifold choke size, THT, BHT, and other relevant parameters. Each type of data has its validation range pre-defined, and any data falling outside this range may be identified as outliers and subsequently removed.

Thus, while traditional well test validation methods have their limitations, emerging technologies and approaches offer promising solutions to overcome these challenges. By leveraging advanced analytics and automation, the accuracy, efficiency, and cost-effectiveness of well test validation processes in the oil and gas industry can be enhanced. The present disclosure leverages artificial intelligence (AI) capability to learn from historical well test data, operational event, and/or well test comments with accepted and rejected flags to build a rule-based deterministic machine learning (ML) model to automatically validate new well tests with a probability of confidence.

### NLP on Well Test Comment

The comment section in the reported well test serves as a valuable space for the operation staff conducting the test to record important information and observations. It serves as a repository for relevant details that may not be captured by the standard data parameters. The comments can include various types of information. Examples of these types of information are shown in Table 2 below.

TABLE 2
Well test comments

| Comment type | Descriptions |
|---|---|
| Additional tests | If any additional tests or operational |
| or operational | activities were conducted in conjunction with |
| activities | the well test, such as well interventions, |
| | stimulations, or data acquisitions, these can |
| | be mentioned in the comments. This provides a |
| | holistic view of the operations performed and |
| | their potential influence on the well test results. |
| Encountered issues | If any challenges or issues were encountered |
| | during the well test, such as equipment |
| | malfunctions, operational difficulties, or |
| | unexpected results, these can be noted in |
| | the comments. This information assists in |
| | identifying potential sources of errors or |
| | deviations in the test data. |
| Equipment failures | In case any equipment failures or replacements |
| or replacements | occurred during the well test, it is important |
| | to record these incidents in the comments. |
| | This helps in understanding any potential |
| | impacts on the test results and ensures proper |
| | documentation of equipment performance. |
| Laboratory test | If water samples were collected during the |
| results for water | well test, the results of laboratory analyses |
| samples | can be recorded in the comments section. This |
| | information helps in assessing water quality |
| | and potential issues related to water production. |
| Special types | If any specific or specialized well tests |
| of well tests | were conducted, such as interference tests, |
| | falloff tests, or injectivity tests, these |
| | details can be documented in the comments. |
| | This helps in providing additional context |
| | and understanding of the testing procedures |
| | and objectives. |
| Suspected anomalies | If there are any suspected anomalies or |
| | unusual observations during the well test, |
| | they can be documented in the comments. |
| | This information can trigger further |
| | investigations or follow-up actions to |
| | validate or address the anomalies. |

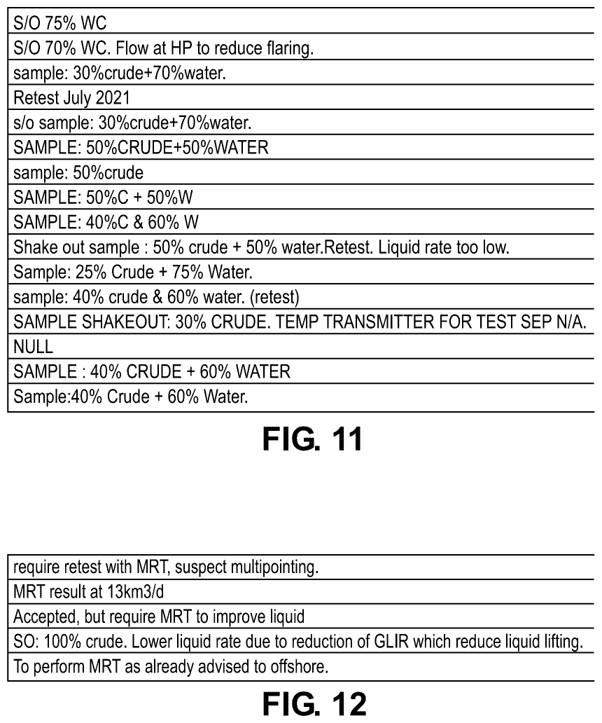

FIG. 11 illustrates a well test comment value extraction, according to an embodiment. FIG. 12 illustrates a well test comment keyword action extraction, according to an embodiment. By utilizing the comment section effectively, the operation staffs responsible for the well test can communicate information, share insights, and document any pertinent details that may impact the interpretation and validation of the test data. It serves as a tool for capturing observations and ensuring comprehensive documentation of the well testing process. The comment section contains valuable information to extract and standardize as input for classification and machine learning purposes.

Conventional hard-coded keyword searches are ineffective due to the various ways of expressing the same concepts, making it difficult to list the possible variations (refer to the example above in FIGS. 11 and 12). To address these challenges, regular expressions may be utilized to identify and replace using patterns with predefined keywords, ensuring standardization. Values extracted from the text are saved as extra measured properties, used for feature building. For instance, the measured Bsw value represents a water cut measured from lab. Furthermore, when translating these comments into classifications, it becomes necessary to determine whether an action has already been performed or is planned by analyzing verb inflections (present, past, or future tense). For example, well test classification is accomplished through NLP-based keyword searches. Whenever base keywords such as MRT (multi-rate test) are found as an action happen in the past, the corresponding well tests are identified as special tests, while the well test validation process focuses exclusively on regular production performance tests.

### Time Series and Variable Correlation Analysis

In conventional mature oil fields, the well performance generally remains stable. However, certain operational activities, back pressure from nearby wells, and deferment events can have an impact on both well performance and well test results. To analyze time domain correlation, time series analysis techniques, such as Auto-correlation coefficient function (ACF) and Partial autocorrelation function (PACF), may be employed on mandatory well test properties, including oil, water, gas production rates, and Bsw, among others. Preliminary findings indicate that the data correlation remains insignificant beyond four consecutive measurements. This observation aligns with the conventional approach that considers a six-month well test correlation.

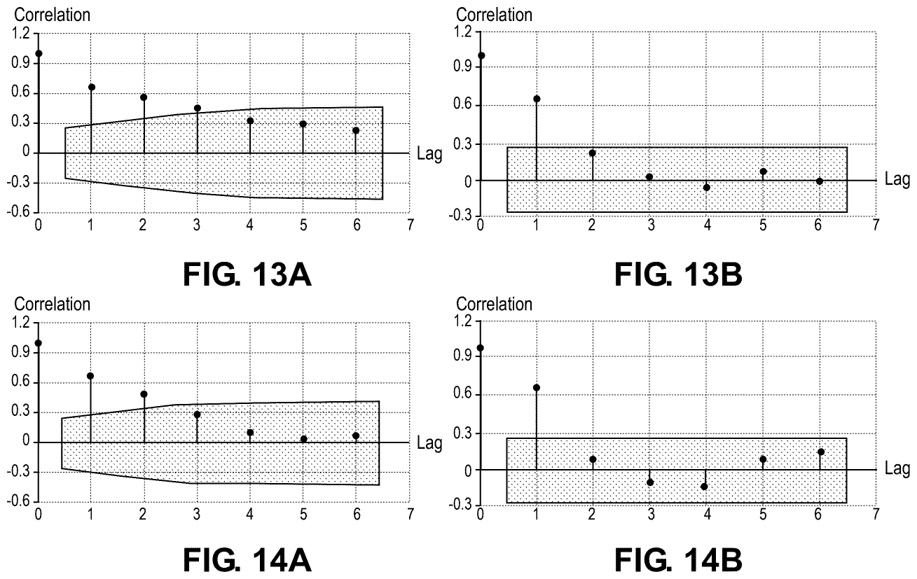

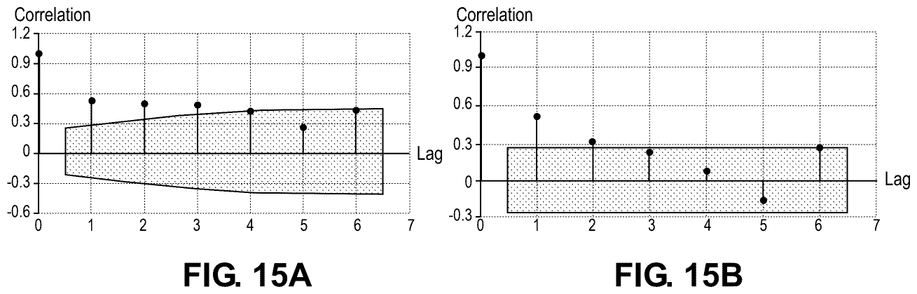

FIG. 13A illustrates ACF auto-correlation for a valid well test property (e.g., Bsw vs number of lag), and FIG. 13B illustrates PACF auto-correlation for the valid well test property (e.g., Bsw vs number of lag), according to an embodiment. FIG. 14A illustrates ACF auto-correlation for a valid well test property (e.g., oil production rate vs number of lag), and FIG. 14B illustrates PACF auto-correlation for the valid well test property (e.g., oil production rate vs number of lag), according to an embodiment. FIG. 15A illustrates ACF auto-correlation for a valid well test property (e.g., water production rate vs number of lag), and FIG. 15B illustrates PACF auto-correlation for the valid well test property (e.g., water production rate vs number of lag), according to an embodiment. Utilizing a rolling window of ‘2, 3, 4’ measurements may be optimal for time series feature building.

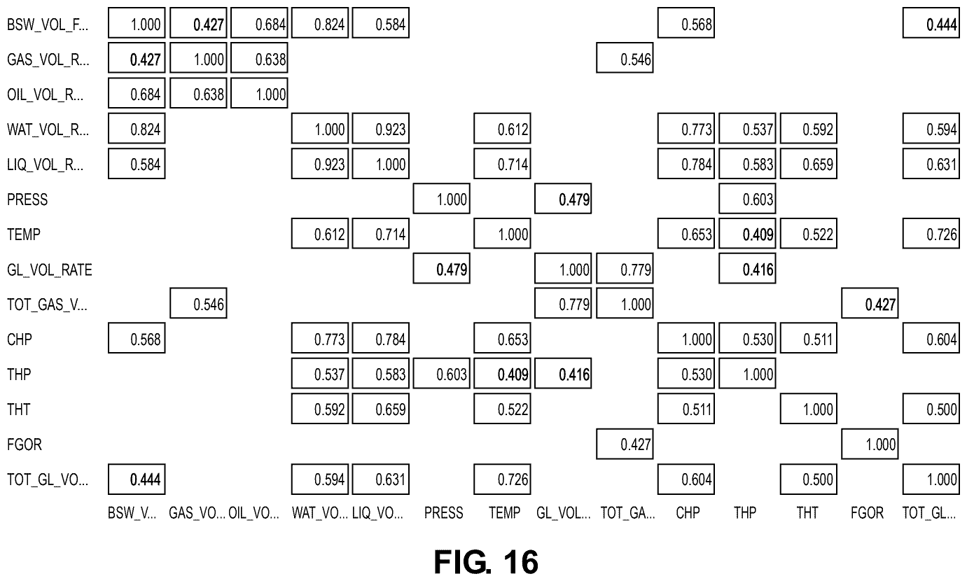

The correlation between different measurements is another factor in determining the quality of well tests. Several correlations have been observed, including: 1) a negative correlation between tubing head pressure (THP) and production rate, assuming the other factors remain constant; 2) a negative correlation between separator pressure and production rate, among others. These correlations, which are derived from domain experience, can also be identified through statistical analysis. In the case study, the cross correlations for the well test properties are calculated. FIG. 16 illustrates correlation matrix, according to an embodiment. In the matrix, larger values indicate higher correlations. To effectively represent the most relevant information, these highly correlated items may be incorporated as new features.

### Machine Learning Model

Feature engineering may be used to effectively train time series classification models. In general, feature engineering refers to domain knowledge and data analytics techniques used to include or reduce the number of features in a dataset. In feature extraction, new features are created from the existing ones to enrich the representation and knowledge, and a subset of these new features is used to replace the original features. These selected features should be able to represent the most relevant information from the original data and domain knowledge. In our case study, based on the correlation and lag feature analysis, time series decomposition features are built including statistic-based features such as average, standard deviation, mean, and rate of changes, as well as correlation-based features, such as the correlation between pressure change and rate change or pressure changes at different locations. Additionally, domain-based features, including operational activities, well test comments, and laboratory comments, may be incorporated. In an example, a total of 472 features are created initially, and the importance of each feature is evaluated to access the prediction power on target. A final set of selected features contains 270 components for training and testing. Once the model considers time series rolling, it is meaningful to compare or correlate with valid well tests and exclude previous invalid tests.

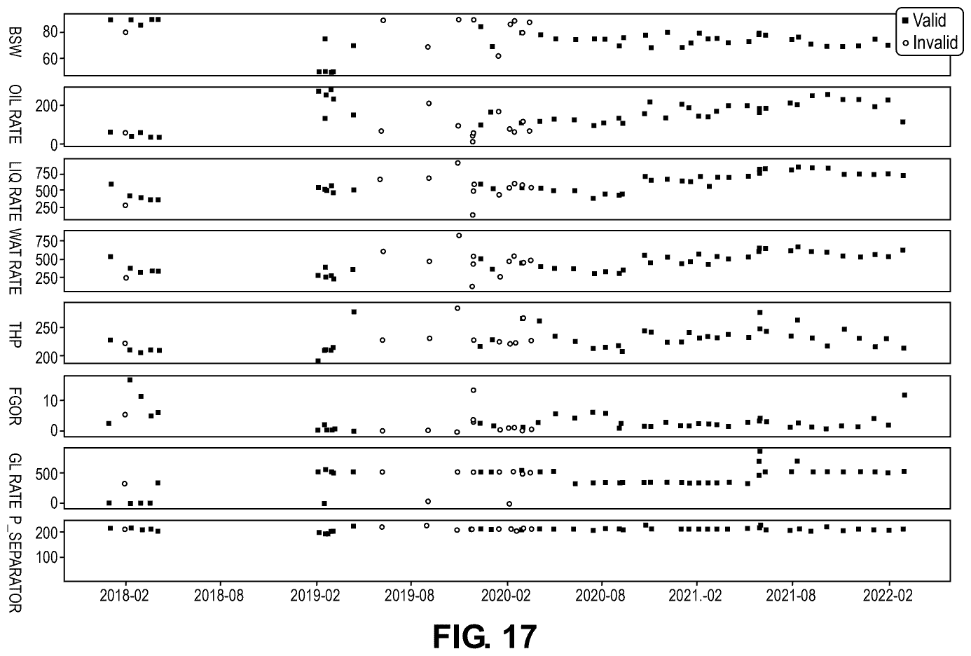

FIG. 17 illustrates a well test history including a plurality of parameters showing valid well tests and invalid well tests, according to an embodiment. The parameters include Bsw, oil rate, liquid rate, water rate, THP, FGOR, GL rate, and P_separator. In this example, the well test data used to build the ML model is from January 2018 to April 2022 from over 100 wells, and includes 3070 records with hybrid frequency from weekly to monthly. The well test data includes 30 properties, which were further derived into 270 components during feature engineering process. The rejection rate for well test validation is approximately 23%. Well test records from May 2022 to March 2023 are saved for validation process.

Supervised learning with labeled data may be used to detect invalid well tests. Classification of invalid well tests is a cost sensitive learning task due to imbalanced data. From a domain point of view, detecting of invalid well tests has an impact compared to other performance matrices. More particularly, if a model fails to identity an invalid well test and lets it go into the system, it may potentially damage other workflows as discussed above. If the ML model predicts a positive result (indicating the detection of an invalid well test), it may be sent for manual validation before a new well test order is initiated.

### Model Evaluation and Results

The conventional approach to measure the performance in binary classification problems is to track true positives, true negatives, false positives, and false negatives, and then calculate metrics like accuracy, precision, recall, and F1-Score. Due to unbalanced labels and cost sensitive learning conditions, prediction performance of the trained ML engines was optimized and evaluated using metrics: F1 score associated with a customized weighted cost matrix. The total cost of a classifier uses cost-weighted sum of the false negatives and false positives.

For training and evaluating performance, the samples may be divided into training and testing datasets (e.g., using an 80/20 split randomly). Various machine learning algorithms may be used to train different ML models using the exact same dataset. Optimization with F1 score and/or weighted cost function may be pre-set during model training. Performance may be compared to select the best model. The performance results may then be ranked, and the best performing machine learning model may be selected.

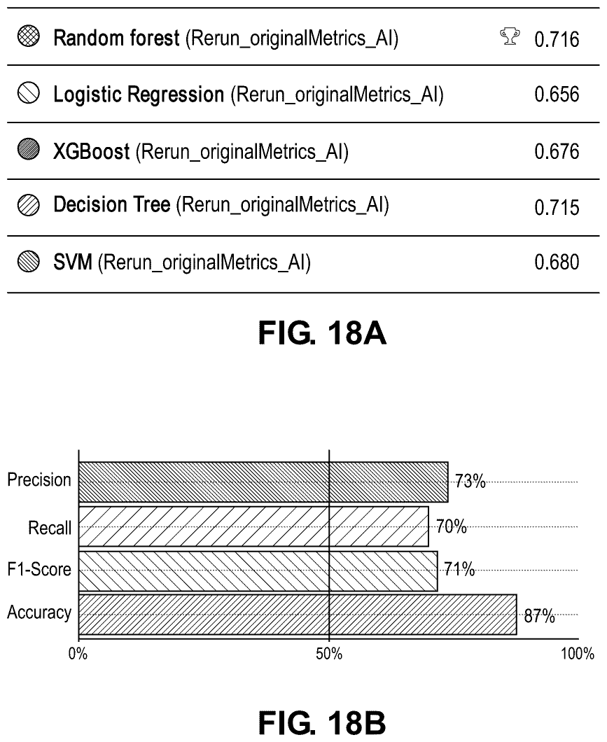

FIGS. 18A and 18B illustrate results from a random forest algorithm, a logistic regression algorithm, an XGBoost algorithm, a decision tree algorithm, and an SVM algorithm, according to an embodiment. Based on the structured well test data only (Table 1), the initial results from the ML analysis indicate that the XGBoost model exhibits the highest performance, achieving a recall score of 71%, precision of 38%, F1 score of 50%, and an overall accuracy of 68%. With the feature extraction from unstructured data using NLP, operational activities and issues may be captured and contribute to feature engineering. Additionally, 25% of false positive and false negative cases are due to human error and inconsistency in decision making and recording. This analysis facilitated data revision and aided in correcting issues in the historical records. After feature extraction from unstructured data using NLP and revision of validation records, a new run may be conducted, and the ML model performance may improve. As shown in FIGS. 18A and 18B, with the threshold adjustment, a recall score of 70%, F1 score of 71%, precision of 73%, and accuracy of 87% may be achieved. In this example, the random forest and decision tree algorithms present the highest F1 score among other algorithms.

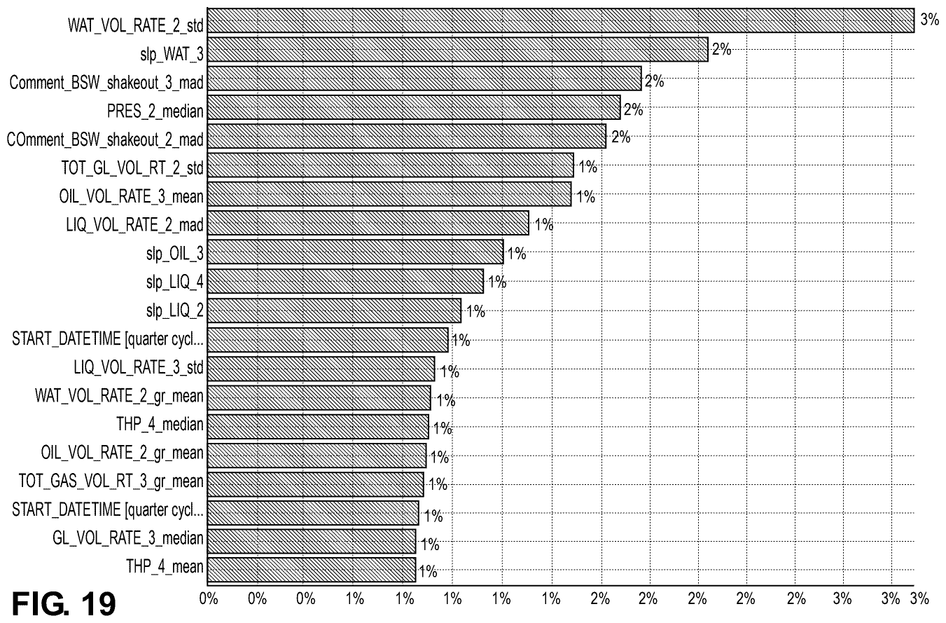

FIG. 19 illustrates a graph showing top feature importance using a random forest algorithm, according to an embodiment. Feature importance refers to tree-based algorithms that calculate a percentage score for the top features contributing to a given model and the percentage score represents the impact of each feature for predicting certain variable.

Production well tests are used on every oil field to evaluate producers' performance and productivity on regular basis. Well test data is the fundamental measurement as input for many workflows, so that well test quality and validation process need to be standardized and ensured timely. An AI solution may be employed to assist and speedup well test validation processes. The proposed solution may be built into an operationalized framework, and with a user action interface, it supports the integration of a user feedback loop to be incorporated effectively. Furthermore, machine learning models may be retained and updated using real-time data, thereby enhancing the efficiency and accuracy of the well test validation process.

Automatic well test validation empowered by ML and NLP offers business benefits to the oil and gas industry. It enhances accuracy and efficiency by quickly identifying errors and anomalies in large volumes of well test data, ranging from numerical to natural language. This improves data quality, enabling reliable decision-making and establishing data-driven workflows that reduce operational costs. It also aids in risk mitigation, regulatory compliance, and continuous improvement of production processes. ML algorithms uncover hidden patterns and correlations, leading to optimization opportunities for production, well performance, and reservoir management. NLP extracts relevant textual data, enriches the knowledge base, and enhances future validations. By leveraging these technologies, companies can maximize the value of their well test data, optimize operations, and drive sustainable business growth.

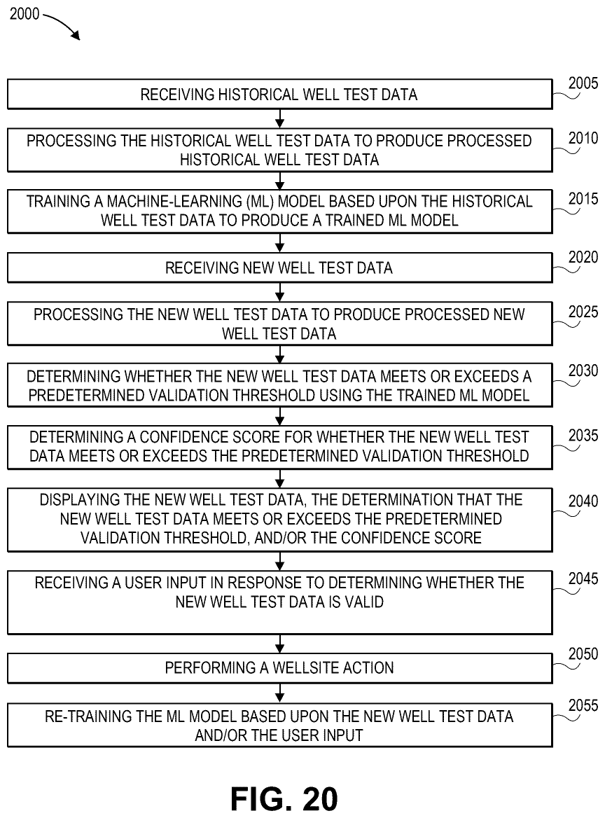

FIG. 20 illustrates a flowchart of a method 2000 for validating a well test, according to an embodiment. An illustrative order of the method 2000 is provided below; however, one or more portions of the method 2000 may be performed in a different order, simultaneously, repeated, or omitted. At least a portion of the method 2000 may be performed by a computing system 2100.

The method 2000 may include receiving historical well test data, as at 2005. The historical well test data may include one or more accepted flags and one or more rejected flags. The one or more accepted flags correspond to a first portion of the historical well test data that has been accepted (e.g., by a user) and the one or more rejected flags correspond to a second portion of the historical well test data that has been rejected (e.g., by the user). The historical well test data may include a well head pressure, an oil/water/gas rate, a separator pressure, a separator temperature, a gas lift injection rate, a choke opening, a casing head pressure, well test comments from the user, or a combination thereof. The user may be a data scientist, a domain user, or an engineer.

The method 2000 may also include processing the historical well test data to produce processed historical well test data, as at 2010. The historical well test data may be processed using a natural language processing (NLP) engine. Processing the historical well test data may include processing the well test comments to extract water cut values, events, and/or operational activities in a structured manner. The events may include a water sample collection, a multi-rate test, and an unstable performance, or a combination thereof. The operational activities may include changes to a low pressure separator, stopping a gas lift, replacement of a Christmas tree, or a combination thereof.

The method 2000 may also include training a machine-learning (ML) model based upon the historical well test data to produce a trained ML model, as at 2015. The ML model may be trained based upon the processed historical well test data. The ML model may be trained based upon the first and second portions of the historical well test data. The ML model may be or include a rule-based deterministic ML model.

The method 2000 may also include receiving new well test data, as at 2020. The new well test data may include the well head pressure, the oil/water/gas rate, the separator pressure, the separator temperature, the gas lift injection rate, the choke opening, the casing head pressure, the well test comments, or a combination thereof. The new well test data may not include the one or more accepted flags and the one or more rejected flags.

The method 2000 may also include processing the new well test data to produce processed new well test data, as at 2025. The new well test data may be processed using the NLP engine. The new well test data may be processed to extract the well test data, the events, the operational activities, and/or deferment activities in a structured manner. The deferment activities may include maintenance, a well intervention for scale or sand removal, an acidizing job, a zone change, reservoir management, water injection, a facility upgrade, or a combination thereof.

The method 2000 may also include determining whether the new well test data meets or exceeds a predetermined validation threshold using the trained ML model, as at 2030. The determination may be based upon the processed new well test data. On one example, the predetermined validation threshold may include a minimum sustained flow rate of hydrocarbons (e.g., 100 barrels per day (BPD)) for more than a predetermined amount of time (e.g., 4 hours). In another example, the predetermined validation threshold may include well head pressure could not be above 600 psi in uncertain field, cant missing data for mandatory well test data types. In response to the new well test data not meeting or exceeding the predetermined validation threshold, root causes and/or contribution factors for not meeting or exceeding the predetermined validation threshold may be determined. The root causes and/or contribution factors may include the new well test data including an oil rate that is greater than a predetermined oil rate threshold (e.g., out of a 6-month trend), the new well head data missing a wellhead pressure measurement, the new wellhead data having a water cut measurement that is greater than a predetermined water cut threshold (e.g., out of a 6-month trend), or a combination thereof.

The method 2000 may also include determining a confidence score for whether the new well test data meets or exceeds the predetermined validation threshold, as at 2035. The determination may be made using the ML model. The determination may be based upon the processed new well test data.

The method 2000 may also include displaying the new well test data, the determination that the new well test data meets or exceeds the predetermined validation threshold, the confidence score, through ML model prediction, as at 2040.

The method 2000 may also include reserving user input in response to determining whether the new well test data is valid, as at 2045. Most decisions rely on auto-validation results from the ML model. However, for a subset of well test data with lower confidence levels in the validation process, the system enables the user to utilize a user interface tool for further analysis on historical trend, accessing to comments and reports, to conduct a rapid investigation and make a final determination.

The method 2000 may also include performing a wellsite action, as at 2050. The wellsite action may be performed in response to the new well test validation results. The wellsite action may be or include ordering a new well test, ordering separate water sample test, confirming the equipment/facility setup to fill the missing information bringing back valid well test data, and further actions on well intervention, performance optimization and so on.

The method 2000 may also include re-training the ML model based upon the new well test data and/or the user input, as at 2055. The ML model may be re-trained in response to a performance of the ML model being less than a predetermined performance threshold.

The method 200 may provide two-way communication between data scientists, domain users, and engineers that may help users to learn and establish healthy habits to avoid inconsistent decision making and human errors. Feedback from users and domain experts regarding the quality of the model prediction may provide valuable insight for potential performance issues, including creating new features or updating existing ones.

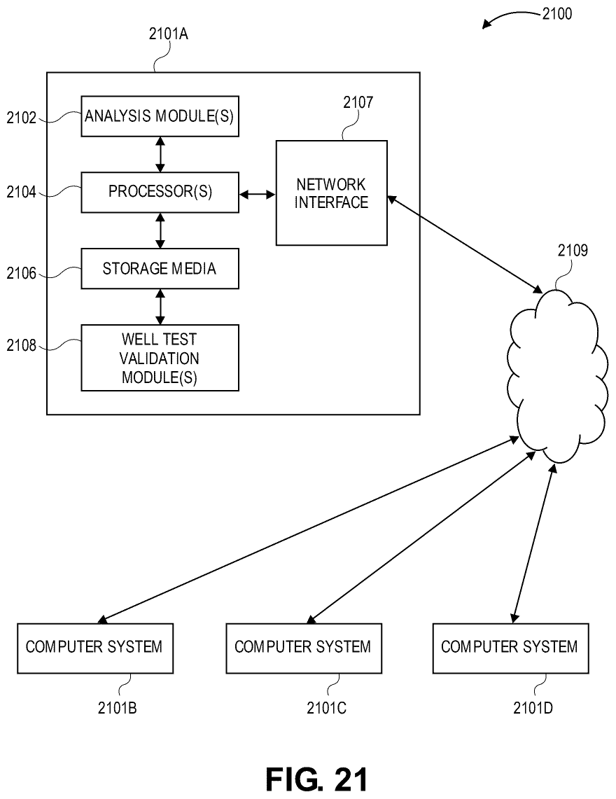

In some embodiments, the methods of the present disclosure may be executed by a computing system. FIG. 21 illustrates an example of such a computing system 2100, in accordance with some embodiments. The computing system 2100 may include a computer or computer system 2101A, which may be an individual computer system 2101A or an arrangement of distributed computer systems. The computer system 2101A includes one or more analysis modules 2102 that are configured to perform various tasks according to some embodiments, such as one or more methods disclosed herein. To perform these various tasks, the analysis module 2102 executes independently, or in coordination with, one or more processors 2104, which is (or are) connected to one or more storage media 2106. The processor(s) 2104 is (or are) also connected to a network interface 2107 to allow the computer system 2101A to communicate over a data network 2109 with one or more additional computer systems and/or computing systems, such as 2101B, 2101C, and/or 2101D (note that computer systems 2101B, 2101C and/or 2101D may or may not share the same architecture as computer system 2101A, and may be located in different physical locations, e.g., computer systems 2101A and 2101B may be located in a processing facility, while in communication with one or more computer systems such as 2101C and/or 2101D that are located in one or more data centers, and/or located in varying countries on different continents).

A processor may include a microprocessor, microcontroller, processor module or subsystem, programmable integrated circuit, programmable gate array, or another control or computing device.

The storage media 2106 may be implemented as one or more computer-readable or machine-readable storage media. Note that while in the example embodiment of FIG. 21 storage media 2106 is depicted as within computer system 2101A, in some embodiments, storage media 2106 may be distributed within and/or across multiple internal and/or external enclosures of computing system 2101A and/or additional computing systems. Storage media 2106 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above may be provided on one computer-readable or machine-readable storage medium, or may be provided on multiple computer-readable or machine-readable storage media distributed in a large system having possibly plural nodes. Such computer-readable or machine-readable storage medium or media is (are) considered to be part of an article (or article of manufacture). An article or article of manufacture may refer to any manufactured single component or multiple components. The storage medium or media may be located either in the machine running the machine-readable instructions, or located at a remote site from which machine-readable instructions may be downloaded over a network for execution.

In some embodiments, computing system 2100 contains one or more well test validation module(s) 2108. It should be appreciated that computing system 2100 is merely one example of a computing system, and that computing system 2100 may have more or fewer components than shown, may combine additional components not depicted in the example embodiment of FIG. 21, and/or computing system 2100 may have a different configuration or arrangement of the components depicted in FIG. 21. The various components shown in FIG. 21 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as ASICs, FPGAs, PLDs, or other appropriate devices. These modules, combinations of these modules, and/or their combination with general hardware are included within the scope of the present disclosure.

Computational interpretations, models, and/or other interpretation aids may be refined in an iterative fashion; this concept is applicable to the methods discussed herein. This may include use of feedback loops executed on an algorithmic basis, such as at a computing device (e.g., computing system 2100, FIG. 21), and/or through manual control by a user who may make determinations regarding whether a given step, action, template, model, or set of curves has become sufficiently accurate for the evaluation of the subsurface three-dimensional geologic formation under consideration.

The foregoing description, for purpose of explanation, has been described with reference to specific embodiments. However, the illustrative discussions above are not intended to be exhaustive or limiting to the precise forms disclosed. Many modifications and variations are possible in view of the above teachings. Moreover, the order in which the elements of the methods described herein are illustrated and described may be re-arranged, and/or two or more elements may occur simultaneously. The embodiments were chosen and described in order to best explain the principles of the disclosure and its practical applications, to thereby enable others skilled in the art to best utilize the disclosed embodiments and various embodiments with various modifications as are suited to the particular use contemplated.

What is claimed is:

1. A method for validating a well test, the method comprising:
receiving historical well test data, wherein the historical well test data comprises one or more accepted flags and one or more rejected flags;
training a machine-learning (ML) model based upon the historical well test data to produce a trained ML model;
receiving new well test data, wherein the new well test data does not include the one or more accepted flags and the one or more rejected flags; and
determining whether the new well test data meets or exceeds a predetermined validation threshold using the trained ML model.

2. The method of claim 1, wherein the historical well test data and the new well test data comprise well test comments from a user.

3. The method of claim 2, further comprising processing the historical well test data to produce processed historical well test data, wherein the historical well test data is processed using a natural language processing (NLP) engine, wherein processing the historical well test data comprises processing the well test comments to extract water cut values, events, and operational activities in a structured manner, wherein the events comprise a water sample collection, a multi-rate test, or an unstable performance, wherein the operational activities comprise changes to a low pressure separator, stopping a gas lift, or replacement of a Christmas tree, and wherein the ML model is trained based upon the processed historical well test data.

4. The method of claim 2, further comprising processing the new well test data to produce processed new well test data, wherein the new well test data is processed using a natural language processing (NLP) engine, wherein the new well test data is processed to extract deferment activities in a structured manner, wherein the deferment activities comprise maintenance, a well intervention for scale or sand removal, an acidizing job, a zone change, reservoir management, water injection, a facility upgrade, or a combination thereof, and wherein the determination whether the new well test data meets or exceeds the predetermined validation threshold is made based upon the processed new well test data.

5. The method of claim 1, wherein the predetermined validation threshold comprises a minimum sustained flow rate of hydrocarbons for more than a predetermined amount of time.

6. The method of claim 1, further comprising determining a cause of the new well test data not meeting or exceeding the predetermined validation threshold, wherein the cause comprises the new well test data including an oil rate that is greater than or less than a predetermined oil rate threshold, a new wellhead data having a water cut measurement that is greater than or less than a predetermined water cut threshold, the new well head data missing a wellhead pressure measurement, or a combination thereof.

7. The method of claim 1, further comprising:
determining a confidence score for whether the new well test data meets or exceeds the predetermined validation threshold using the trained ML model; and
receiving user input in response to the determination whether the new well test data meets or exceeds the predetermined validation threshold and the confidence score.

8. The method of claim 7, further comprising re-training the ML model based upon the new well test data and the user input, wherein the trained ML model is re-trained in response to a performance of the trained ML model being less than a predetermined performance threshold.

9. The method of claim 1, further comprising displaying the new well test data and the determination whether the new well test data meets or exceeds the predetermined validation threshold.

10. The method of claim 1, further comprising performing a wellsite action in response to the determination whether the new well test data meets or exceeds the predetermined validation threshold.

11. A computing system, comprising:
one or more processors; and
a memory system comprising one or more non-transitory computer-readable media storing instructions that, when executed by at least one of the one or more processors, cause the computing system to perform operations, the operations comprising:
receiving historical well test data, wherein the historical well test data comprises one or more accepted flags and one or more rejected flags, wherein the one or more accepted flags correspond to a first portion of the historical well test data that has been accepted, wherein the one or more rejected flags correspond to a second portion of the historical well test data that has been rejected;
training a machine-learning (ML) model based upon the historical well test data to produce a trained ML model;
receiving new well test data, wherein the new well test data does not include the one or more accepted flags and the one or more rejected flags; and
determining whether the new well test data meets or exceeds a predetermined validation threshold using the trained ML model, wherein the predetermined validation threshold comprises a minimum sustained flow rate of hydrocarbons for more than a predetermined amount of time.

12. The computing system of claim 11, wherein the historical well test data and the new well test data comprise well test comments from a user and a well head pressure, an oil/water/gas rate, a separator pressure, a separator temperature, a gas lift injection rate, a choke opening, a casing head pressure, or a combination thereof.

13. The computing system of claim 11, wherein the operations further comprise:
processing the historical well test data to produce processed historical well test data, wherein the historical well test data is processed using a natural language processing (NLP) engine, wherein processing the historical well test data comprises processing the well test comments to extract water cut values, events, and operational activities in a structured manner, wherein the events comprise a water sample collection, a multi-rate test, or an unstable performance, wherein the operational activities comprise changes to a low pressure separator, stopping a gas lift, or replacement of a Christmas tree, and wherein the ML model is trained based upon the processed historical well test data; and
processing the new well test data to produce processed new well test data, wherein the new well test data is processed using the NLP engine, wherein the new well test data is processed to extract the well test data, the events, the operational activities, and deferment activities in a structured manner, wherein the deferment activities comprise maintenance, a well intervention for scale or sand removal, an acidizing job, a zone change, reservoir management, water injection, a facility upgrade, or a combination thereof, and wherein the determination whether the new well test data meets or exceeds the predetermined validation threshold is made based upon the processed new well test data.

14. The computing system of claim 11, wherein the minimum sustained flow rate is 100 barrels per day, and the predetermined amount of time is four hours, wherein, in response to the new well test data not meeting or exceeding the predetermined validation threshold, root causes and/or contribution factors for not meeting or exceeding the predetermined validation threshold are determined, and wherein the root causes and/or contribution factors comprise the new well test data including an oil rate that is greater than a predetermined oil rate threshold, the new well head data missing a wellhead pressure measurement, a new wellhead data having a water cut measurement that is greater than a predetermined water cut threshold, or a combination thereof.

15. The computing system of claim 11, wherein the operations further comprise:
determining a confidence score for whether the new well test data meets or exceeds the predetermined validation threshold using the trained ML model, wherein the determination is based upon the processed new well test data;
receiving user input in response to the determination whether the new well test data meets or exceeds the predetermined validation threshold and/or the confidence score, wherein the user input is received in response to the confidence score being less than a predetermined confidence threshold;
performing a wellsite action in response to the determination whether the new well test data meets or exceeds the predetermined validation threshold, the confidence score, and the user input, wherein the wellsite action comprises generating or transmitting a signal that causes a physical action to occur at a wellsite, and wherein the physical action comprises selecting where to drill a wellbore, drilling the wellbore, varying a weight and/or torque on a drill bit that is drilling the wellbore, varying a drilling trajectory of the wellbore, or varying a concentration and/or flow rate of a fluid pumped into the wellbore; and
re-training the ML model based upon the new well test data and the user input, wherein the trained ML model is re-trained in response to a performance of the trained ML model being less than a predetermined performance threshold.

16. A non-transitory computer-readable medium storing instructions that, when executed by one or more processors of a computing system, cause the computing system to perform operations, the operations comprising:
receiving historical well test data, wherein the historical well test data comprises one or more accepted flags and one or more rejected flags, wherein the one or more accepted flags correspond to a first portion of the historical well test data that has been accepted, wherein the one or more rejected flags correspond to a second portion of the historical well test data that has been rejected;
training a machine-learning (ML) model based upon the historical well test data to produce a trained ML model, wherein the ML model is a rule-based deterministic ML model;
receiving new well test data, wherein the new well test data does not include the one or more accepted flags and the one or more rejected flags; and
determining whether the new well test data meets or exceeds a predetermined validation threshold using the trained ML model, wherein the predetermined validation threshold comprises a minimum sustained flow rate of hydrocarbons for more than a predetermined amount of time.

17. The non-transitory computer-readable medium of claim 16, wherein the historical well test data and the new well test data comprise well test comments from a user, a well head pressure, an oil/water/gas rate, a separator pressure, a separator temperature, a gas lift injection rate, a choke opening, and a casing head pressure, and wherein the user comprises a data scientist, a domain user, or an engineer.

18. The non-transitory computer-readable medium of claim 17, wherein the operations further comprise:
processing the historical well test data to produce processed historical well test data, wherein the historical well test data is processed using a natural language processing (NLP) engine, wherein processing the historical well test data comprises processing the well test comments to extract water cut values, events, and operational activities in a structured manner, wherein the events comprise a water sample collection, a multi-rate test, and an unstable performance, wherein the operational activities comprise changes to a low pressure separator, stopping a gas lift, and replacement of a Christmas tree, and wherein the ML model is trained based upon the processed historical well test data; and
processing the new well test data to produce processed new well test data, wherein the new well test data is processed using the NLP engine, wherein the new well test data is processed to extract the well test data, the events, the operational activities, and deferment activities in the structured manner, wherein the deferment activities comprise maintenance, a well intervention for scale or sand removal, an acidizing job, a zone change, reservoir management, water injection, a facility upgrade, or a combination thereof, and wherein the determination whether the new well test data meets or exceeds the predetermined validation threshold is made based upon the processed new well test data.

19. The non-transitory computer-readable medium of claim 18, wherein the minimum sustained flow rate is 100 barrels per day, and the predetermined amount of time is four hours, wherein, in response to the new well test data not meeting or exceeding the predetermined validation threshold, root causes and/or contribution factors for not meeting or exceeding the predetermined validation threshold are determined, and wherein the root causes and/or contribution factors comprise the new well test data including an oil rate that is greater than a predetermined oil rate threshold, the new well head data missing a wellhead pressure measurement, the new wellhead data having a water cut measurement that is greater than a predetermined water cut threshold, or a combination thereof.

20. The non-transitory computer-readable medium of claim 19, wherein the operations further comprise:
determining a confidence score for whether the new well test data meets or exceeds the predetermined validation threshold using the trained ML model, wherein the determination is based upon the processed new well test data;
receiving user input in response to the determination whether the new well test data meets or exceeds the predetermined validation threshold and/or the confidence score, wherein the user input is received in response to the confidence score being less than a predetermined confidence threshold;
displaying the new well test data, the determination whether the new well test data meets or exceeds the predetermined validation threshold, the confidence score, and the user input;
performing a wellsite action in response to the determination whether the new well test data meets or exceeds the predetermined validation threshold, the confidence score, and the user input, wherein the wellsite action comprises generating or transmitting a signal that causes a physical action to occur at a wellsite, and wherein the physical action comprises selecting where to drill a wellbore, drilling the wellbore, varying a weight and/or torque on a drill bit that is drilling the wellbore, varying a drilling trajectory of the wellbore, or varying a concentration and/or flow rate of a fluid pumped into the wellbore; and
re-training the ML model based upon the new well test data and the user input, wherein the trained ML model is re-trained in response to a performance of the trained ML model being less than a predetermined performance threshold.
